(19) United States
(12) Patent Application Publication
(10) Pub. No.: US 2009/0085123 A1
(43) Pub. Date: Apr. 2, 2009

(54) SEMICONDUCTOR DEVICE AND METHOD FOR FABRICATING THE SAME

(76) Inventor: Yoshihiro SATO, Hyogo (JP)

Correspondence Address: MCDERMOTT WILL & EMERY LLP, 600 13TH STREET, NW, WASHINGTON, DC, 20005-3096, US

(21) Appl. No.: 12/211,557

(22) Filed: Sep. 16, 2008

(30) Foreign Application Priority Data
Sep. 28, 2007 (JP) 2007-253260

(51) Int. Cl. H01L 29/423; H01L 21/8238

(52) U.S. Cl. 257/369; 438/199; 438/218; 257/E29.128

(57) ABSTRACT

A semiconductor device comprises a first MIS transistor and a second MIS transistor. The first MIS transistor includes a first sidewall formed on a side surface of a first gate electrode, and including a first inner sidewall having an L-shaped cross-section and a first outer sidewall. The second MIS transistor includes a second sidewall formed on a side surface of a second gate electrode, and including a second inner sidewall having an L-shaped cross-section and a second outer sidewall, a trench provided in a region outside the second sidewall in a second active region, and a silicon mixed-crystal layer formed in the trench, for causing first stress in a gate length direction of a channel region in the second active region. A height of an upper end of the second inner sidewall is lower than a height of an upper end of the first inner sidewall.

### CROSS REFERENCE TO RELATED APPLICATIONS

This Non-provisional application claims priority under 35 U.S.C. §119(a) on Patent Application No. 2007-253260 filed in Japan on Sep. 28, 2007, the entire contents of which are hereby incorporated by reference.

### BACKGROUND OF THE INVENTION

1. Field of the Invention

The present invention relates to a semiconductor device and its fabricating method. More particularly, the present invention relates to a semiconductor device in which an epitaxially grown silicon mixed-crystal layer is provided in a source/drain formation region of a Metal-Insulator-Semiconductor Field-Effect Transistor (MISFET), and the drive ability of the transistor is improved by a strain technique using the silicon mixed-crystal layer, and a method for fabricating the semiconductor device.

2. Description of the Related Art

A strain technique for improving the drive ability of a transistor by applying stress to a channel region of a MISFET (hereinafter referred to as a “MIS transistor”) has been developed toward practical use so as to enhance the performance of semiconductor integrated circuit devices. In p-type MIS transistors, it is known that the mobility of carriers is improved by applying compressive stress to the channel region in the gate length direction. A method for applying compressive stress to the channel region has been proposed in which a SiGe layer having a larger lattice constant than that of a silicon substrate is formed in a source/drain formation region (see, for example, Patent Document 1: Japanese Unexamined Patent Application Publication No. 2006-196549, Non-Patent Document 1: T. Ghani et al., “A 90 nm High Volume Manufacturing Logic Technology Featuring Novel 45 nm Gate Length Strained Silicon CMOS Transistors”, IEDM Tech. Digest, pp. 978-980, 2003, and Non-Patent Document 2: Z. Luo et al., “Design of High Performance PFETs with Strained Si Channel and Laser Anneal”, IEDM Tech. Digest, pp. 495-498, 2005).

A method for fabricating a conventional semiconductor device comprising a Complementary Metal-Insulator Semiconductor (CMIS) element including an n-type MIS transistor and a p-type MIS transistor provided on the same substrate, where a silicon mixed-crystal layer made of a SiGe layer is provided in a source/drain formation region of the p-type MIS transistor, will be briefly described below with reference to FIGS. 13A to 13D, FIGS. 14A to 14C, and FIGS. 15A to 15C. FIGS. 13A to 13D, FIGS. 14A to 14C, and FIGS. 15A to 15C are cross-sectional views showing major steps of fabricating the conventional semiconductor device in order of when the steps are performed. In these figures, an Xa-Xa region shown on the left-hand side indicates an n-type MIS formation region NTR, and an Xb-Xb region shown on the right-hand side indicates a p-type MIS formation region PTR.

Initially, as shown in FIG. 13A, an isolation region 101 is selectively formed in an upper portion of a semiconductor substrate 100 made of p-type silicon. Thereby, a first active region 100a made of the semiconductor substrate 100 that is surrounded by the isolation region 101 is formed in the n-type MIS formation region NTR, while a second active region 100b made of the semiconductor substrate 100 that is surrounded by the isolation region 101 is formed in the p-type MIS formation region PTR. Thereafter, a p-type well region 102a is formed in the n-type MIS formation region NTR of the semiconductor substrate 100, while an n-type well region 102b is formed in the p-type MIS formation region PTR of the semiconductor substrate 100.

Next, as shown in FIG. 13B, a gate insulating film formation film 103 made of a silicon oxide film, a gate electrode formation film 104 made of a polysilicon film, and a protection film 105 made of a silicon oxide film are successively formed on the first active region 100a and the second active region 100b.

Next, as shown in FIG. 13C, the protection film 105, the gate electrode formation film 104, and the gate insulating film formation film 103 are successively subjected to patterning by photolithography and dry etching, thereby forming a first gate insulating film 103a, a first gate electrode 104a and a first protection film 105a on the first active region 100a, and a second gate insulating film 103b, a second gate electrode 104b and a second protection film 105b on the second active region 100b. Next, an n-type source/drain region 106a having a relatively shallow junction depth is formed outside the first gate electrode 104a in the first active region 100a, while a p-type source/drain region 106b having a relatively shallow junction depth is formed outside the second gate electrode 104b in the second active region 100b.

Next, as shown in FIG. 13D, a silicon nitride film is deposited on an entire surface of the semiconductor substrate 100, and thereafter, anisotropic etching is performed with respect to the silicon nitride film, thereby forming a first sidewall 107a on a side surface of the first gate electrode 104a and a second sidewall 107b on a side surface of the second gate electrode 104b.

Next, as shown in FIG. 14A, a protection oxide film 108 having a film thickness of 20 nm is deposited on an entire surface of the semiconductor substrate 100.

Next, as shown in FIG. 14B, a resist 109 that covers the n-type MIS formation region NTR and has an opening in the p-type MIS formation region PTR is formed on the protection oxide film 108, and thereafter, the protection oxide film 108 formed in the p-type MIS formation region PTR is etched by dry etching using the resist 109 as a mask, thereby exposing a surface of source/drain formation region in the second active region 100b. In this case, a fourth sidewall 108b made of the protection oxide film 108 is formed on a side surface of the second sidewall 107b.

Next, as shown in FIG. 14C, the resist 109 is removed, and thereafter, the second active region 100b whose surface is exposed is etched to a desired depth, thereby forming a trench 110.

Next, as shown in FIG. 15A, a silicon mixed-crystal layer 111 made of a p-type SiGe layer is selectively epitaxially grown by, for example, Chemical Vapor Deposition (CVD) so that the trench 110 is filled with the silicon mixed-crystal layer 111.

Next, as shown in FIG. 15B, the protection oxide film 108 and the first protection film 105a in the n-type MIS formation region NTR are etched by dry etching so that a surface of a source/drain formation region in the first active region 100a and an upper surface of the first gate electrode 104a are exposed, while the second protection film 105b in the p-type MIS formation region PTR is etched so that an upper surface of the second gate electrode 104b is exposed. In this case, a third sidewall 108a made of the protection oxide film 108 is formed on a side surface of the first sidewall 107a.

Next, as shown in FIG. 15C, an n-type source/drain region 112a having a relatively deep junction depth is formed outside the third sidewall 108a in the first active region 100a, while a p-type source/drain region 112b having a relatively deep junction depth is formed in a region of the silicon mixed-crystal layer 111 outside the fourth sidewall 108b in the second active region 100b. Thereafter, using a salicide technique, first and second silicide layers 113a and 113b are formed in upper portions of the first and second gate electrodes 104a and 104b, while third and fourth silicide layers 114a and 114b are formed in upper portions of the deep n-type source/drain region 112a and the deep p-type source/drain region 112b.

Thus, a CMIS element is formed that does not have a silicon mixed-crystal layer in the source/drain formation region of the n-type MIS transistor and has a silicon mixed-crystal layer only in the source/drain formation region of the p-type MIS transistor.

In general, compressive stress that is applied to the channel region by the silicon mixed-crystal layer made of a SiGe layer, improves the drive ability of the p-type MIS transistor, but deteriorates the drive ability of the n-type MIS transistor. Therefore, in a semiconductor device having a CMIS structure in which an n-type MIS transistor and a p-type MIS transistor are provided on the same substrate, a SiGe layer needs to be formed in the source/drain formation region of the p-type MIS transistor, while a SiGe layer needs not to be formed in the source/drain formation region of the n-type MIS transistor.

Therefore, in conventional semiconductor device fabricating methods, in order to prevent epitaxial growth of a SiGe layer on the first active region 100a in the n-type MIS formation region NTR, the protection oxide film 108 is deposited on an entire surface of the semiconductor substrate 100 (see FIG. 14A), and thereafter, only the protection oxide film 108 in the p-type MIS formation region PTR is etched while the first active region 100a in the n-type MIS formation region NTR is kept covered with the protection oxide film 108 (see FIG. 14B). Thus, the trench 110 is formed only in the second active region 100b of the p-type MIS formation region PTR (see FIG. 14C), and the silicon mixed-crystal layer 111 is selectively epitaxially grown in the trench 110 (see FIG. 15A).

However, when the protection oxide film 108 in the p-type MIS formation region PTR is etched, the protection oxide film 108 remains as the fourth sidewall 108b on the second sidewall 107b (see FIG. 14B), so that the trench 110 is formed in a region outside the fourth sidewall 108b, but not outside the second sidewall 107b (see FIG. 14C), and therefore, the trench 110 cannot be formed close to the channel region in the second active region 100b. Therefore, in the p-type MIS transistor, the silicon mixed-crystal layer 111 formed in the trench 110 is formed at a distance from the channel region, so that compressive stress caused by the silicon mixed-crystal layer 111 cannot be effectively applied to the channel region in the gate length direction.

Also, as miniaturization of semiconductor devices is advanced, the gap between sidewalls formed on the side surfaces of adjacent gate electrodes in the p-type MIS transistor becomes narrower. Therefore, in conventional semiconductor device fabricating methods, when the protection oxide film is formed (see FIG. 14A), the protection oxide film is formed and buried between the sidewalls, so that the film thickness of the protection oxide film buried between the sidewalls is larger than the formation film thickness of the protection oxide film (e.g., the film thickness of the protection oxide film formed on the second gate electrode 104b). Therefore, when the protection oxide film 108 in the p-type MIS formation region PTR is etched (see FIG. 14B), the etching needs to be excessively performed so as to remove the protection oxide film buried between the sidewalls so that a surface of the second active region 100b (specifically, a surface of the source/drain formation region) is exposed. In this case, the second protection film 105b as well as the protection oxide film formed on the second gate electrode 104b are removed, so that an upper surface of the second gate electrode 104b is exposed. Therefore, when the trench 110 is formed (see FIG. 14C), a trench is also formed in the second gate electrode 104b, so that when the silicon mixed-crystal layer 111 is formed (see FIG. 15A), a SiGe layer is also disadvantageously formed in the trench.

Thus, in conventional semiconductor device fabricating methods, since the unnecessary sidewall 108b remains, the silicon mixed-crystal layer 111 cannot be formed close to the channel region of the p-type MIS transistor. In addition, as miniaturization of semiconductor devices is advanced, an unnecessary SiGe layer is likely to be formed in the second gate electrode 104b, so that the silicon mixed-crystal layer 111 cannot be formed with accuracy.

Note that it has been described above by way of a specific example that, in a CMIS-structure semiconductor device, a silicon mixed-crystal layer made of, for example, a SiGe layer (a silicon mixed-crystal layer that causes compressive stress in the gate length direction of the channel region of the p-type MIS transistor) is formed in the source/drain formation region of the p-type MIS transistor. Conversely, when a silicon mixed-crystal layer made of, for example, a SiC layer (a silicon mixed-crystal layer that causes tensile stress in the gate length direction of the channel region of the n-type MIS transistor) is formed in the source/drain formation region of the n-type MIS transistor, a problem similar to that described above arises. Specifically, the silicon mixed-crystal layer (SiC layer) cannot be formed close to the channel region of the n-type MIS transistor. In addition, as miniaturization of semiconductor devices is advanced, an unnecessary SiC layer is likely to be formed in the gate electrode of the n-type MIS transistor, so that the silicon mixed-crystal layer cannot be formed with accuracy.

### SUMMARY OF THE INVENTION

In view of the above-described problems, an object of the present invention is to provide a CMIS-structure semiconductor device in which a silicon mixed-crystal layer is formed either in a source/drain formation region of an n-type MIS transistor or in a source/drain formation region of a p-type MIS transistor with accuracy.

To achieve the object, a semiconductor device according to an aspect of the present invention comprises a first MIS transistor and a second MIS transistor. The first MIS transistor includes a first active region surrounded by an isolation region in a semiconductor substrate, a first gate insulating film formed on the first active region, a first gate electrode formed on the first gate insulating film, and a first sidewall formed on a side surface of the first gate electrode, and including a first inner sidewall having an L-shaped cross-section and a first outer sidewall formed on the first inner sidewall. The second MIS transistor includes a second active region surrounded by the isolation region in the semiconductor substrate, a second gate insulating film formed on the second active region, a second gate electrode formed on the second gate insulating film, a second sidewall formed on a side surface of the second gate electrode, and including a second inner sidewall having an L-shaped cross-section and a second outer sidewall formed on the second inner sidewall, a trench provided in a region outside the second sidewall in the second active region, and a silicon mixed-crystal layer formed in the trench, for causing first stress in a gate length direction of a channel region in the second active region. A height of an upper end of the second inner sidewall is lower than a height of an upper end of the first inner sidewall.

According to the semiconductor device of the aspect of the present invention, as is different from the conventional art, an unnecessary sidewall does not remain on the second sidewall. Therefore, the silicon mixed-crystal layer can be formed close to the channel region in the second active region, so that first stress can be effectively applied in the gate length direction of the channel region by the silicon mixed-crystal layer, resulting in an effective improvement in the drive ability of the second MIS transistor.

In the semiconductor device of the aspect of the present invention, the upper end height of the second inner sidewall is preferably lower by at least a film thickness of the first inner sidewall than the upper end height of the first inner sidewall.

The semiconductor device of the aspect of the present invention preferably further comprises a first silicide layer formed on the first gate electrode, and a second silicide layer formed on the second gate electrode. The second silicide layer preferably has a larger film thickness than that of the first silicide layer.

In the semiconductor device of the aspect of the present invention, the first inner sidewall and the second inner sidewall are preferably made of a silicon oxide film, and the first outer sidewall and the second outer sidewall are preferably made of a silicon nitride film.

The semiconductor device of the aspect of the present invention preferably further comprises a first offset spacer formed between the side surface of the first gate electrode and the first sidewall, and a second offset spacer formed between the side surface of the second gate electrode and the second sidewall.

The semiconductor device of the aspect of the present invention preferably further comprises a first-conductivity type source/drain region formed in a region outside the first sidewall in the first active region, and a second-conductivity type source/drain region formed in a region including the silicon mixed-crystal layer outside the second sidewall in the second active region.

In the semiconductor device of the aspect of the present invention, second stress is preferably applied, in a gate length direction, to a channel region in the first active region, and the first stress is preferably applied, in the gate length direction, to a channel region in the second active region. The second stress is preferably tensile stress, and the first stress is preferably compressive stress.

Thus, by the first stress applied by the silicon mixed-crystal layer in the gate length direction of the channel region in the second active region, the drive ability of the second MIS transistor can be effectively improved, and in addition, by the second stress memorized in the gate length direction of the channel region in the first active region, the drive ability of the first MIS transistor can be improved.

In the semiconductor device of the aspect of the present invention, the first gate electrode and the second gate electrode preferably have different average grain sizes of silicon film.

In the semiconductor device of the aspect of the present invention, the first MIS transistor is preferably an n-type MIS transistor. The second MIS transistor is preferably a p-type MIS transistor. The silicon mixed-crystal layer is preferably made of a SiGe layer. The first stress is preferably compressive stress.

In the semiconductor device of the aspect of the present invention, the first MIS transistor is preferably a p-type MIS transistor. The second MIS transistor is preferably an n-type MIS transistor. The silicon mixed-crystal layer is preferably made of a SiC layer. The first stress is preferably tensile stress.

To achieve the object, a method according to an aspect of the present invention is provided for fabricating a semiconductor device comprising a first MIS transistor having a first gate insulating film and a first gate electrode and a second MIS transistor having a second gate insulating film and a second gate electrode. The method comprises the steps of (a) forming a first active region and a second active region surrounded by an isolation region in a semiconductor substrate, (b) forming the first gate insulating film and the first gate electrode on the first active region, and forming the second gate insulating film and the second gate electrode on the second active region, (c) after step (b), successively forming a first insulating film and a second insulating film on the semiconductor substrate, (d) etching the second insulating film to form a first outer sidewall on a side surface of the first gate electrode with the first insulating film being interposed between the first outer sidewall and the first gate electrode, and to form a second outer sidewall on a side surface of the second gate electrode with the first insulating film being interposed between the second outer sidewall and the second gate electrode, (e) after step (d), etching the first insulating film on the second active region to form a second inner sidewall having an L-shaped cross-section between the second gate electrode and the second outer sidewall, thereby forming a second sidewall including the second inner sidewall and the second outer sidewall, (f) forming a trench in a region outside the second sidewall in the second active region, (g) selectively forming, in the trench, a silicon mixed-crystal layer for causing first stress in a gate length direction of a channel region in the second active region, and (h) after step (g), etching the first insulating film on the first active region to form a first inner sidewall having an L-shaped cross-section between the first gate electrode and the first outer sidewall, thereby forming a first sidewall including the first inner sidewall and the first outer sidewall.

According to the semiconductor device fabricating method of the aspect of the present invention, when the silicon mixed-crystal layer is formed, the first insulating film formed on the first active region is used as a prevention film that prevents a silicon mixed-crystal layer from being formed on the first active region. The first insulating film functioning as this prevention film is formed before formation of the first and second outer sidewalls, so that the first insulating film on the second active region, which is formed under the second outer sidewall, can be etched. Therefore, the first insulating film remains on the second outer sidewall, i.e., an unnecessary sidewall does not remain. Therefore, the silicon mixed-crystal layer can be formed close to the channel region in the second active region, so that the first stress caused by the silicon mixed-crystal layer can be effectively applied in the gate length direction of the channel region, thereby making it possible to effectively improve the drive ability of the second MIS transistor.

In addition, even when the gap between the sidewalls formed on the side surfaces of adjacent gate electrodes becomes narrower in the second MIS transistor as miniaturization of semiconductor devices is advanced, since the first insulating film functioning as the prevention film during formation of the silicon mixed-crystal layer is formed before formation of the first and second outer sidewalls, the prevention film (protection oxide film) is not buried between the sidewalls, so that an unnecessary silicon mixed-crystal layer is not formed in the second gate electrode, as is different from the conventional art.

Thus, the silicon mixed-crystal layer can be formed only in the source/drain formation region of the second MIS transistor with accuracy.

Moreover, the first insulating film not only functions as the prevention film, but also becomes the second inner sidewall to form a portion of the second sidewall, and becomes the first inner sidewall to form a portion of the first sidewall. Therefore, as is different from the conventional art, the protection oxide film functioning as the prevention film does not need to be additionally formed, so that the number of steps can be reduced.

In the semiconductor device fabricating method of the aspect of the present invention, step (h) preferably includes etching the second inner sidewall. A height of an upper end of the second inner sidewall is preferably lower than a height of an upper end of the first inner sidewall.

In the semiconductor device fabricating method of the aspect of the present invention, the first inner sidewall and the second inner sidewall are preferably made of a silicon oxide film, and the first outer sidewall and the second outer sidewall are preferably made of a silicon nitride film.

The semiconductor device fabricating method of the aspect of the present invention preferably further comprises (i) after step (h), forming a first first-conductivity type source/drain region in a region outside the first sidewall in the first active region, and forming a first second-conductivity type source/drain region in a region including the silicon mixed-crystal layer outside the second sidewall in the second active region.

The semiconductor device fabricating method of the aspect of the present invention preferably further comprises (j) after step (h), forming a first silicide layer on the first gate electrode, and forming a second silicide layer on the second gate electrode. The second silicide layer preferably has a larger film thickness than that of the first silicide layer.

The semiconductor device fabricating method of the aspect of the present invention preferably further comprises (k) after step (d) and before step (e), forming a surface protection film on the semiconductor substrate. Step (e) preferably includes etching the surface protection film on the second active region before etching the first insulating film on the second active region. Step (h) preferably includes etching the surface protection film on the first active region before etching the first insulating film on the first active region.

Thereby, when the silicon mixed-crystal layer is formed, a multilayer film of the first insulating film and the surface protection film formed on the first active region can be used as a protection film for protecting formation of the silicon mixed-crystal layer on the first active region. Therefore, a film thickness of the first insulating film can be reduced while preventing formation of the silicon mixed-crystal layer on the first active region.

The semiconductor device fabricating method of the aspect of the present invention preferably further comprises (l) after step (g) and before step (h), or after step (h), memorizing second stress in a channel region of the first active region. The second stress is preferably tensile stress, and the first stress is preferably compressive stress.

Thereby, the first stress is effectively applied in the gate length direction of the channel region in the second MIS transistor by the silicon mixed-crystal layer, so that the drive ability of the second MIS transistor can be effectively improved. In addition, the second stress is applied in the gate length direction of the channel region in the first MIS transistor, so that the drive ability of the first MIS transistor can be improved.

In the semiconductor device fabricating method of the aspect of the present invention, step (l) preferably includes (l1) forming a stressor insulating film on the semiconductor substrate, (l2) removing the stressor insulating film on the second active region, (l3) after step (l2), performing a heat treatment with respect to the semiconductor substrate, and (l4) after step (l1), removing the stressor insulating film on the first active region. In step (l3), the second stress is preferably applied from the stressor insulating film on the first active region to the first active region by the heat treatment, so that the second stress is memorized in the channel region of the first active region.

In the semiconductor device fabricating method of the aspect of the present invention, the first MIS transistor is preferably an n-type MIS transistor. The second MIS transistor is preferably a p-type MIS transistor. Step (g) is preferably a step of forming a SiGe layer as the silicon mixed-crystal layer. The first stress is preferably compressive stress.

In the semiconductor device fabricating method of the aspect of the present invention, the first MIS transistor is preferably a p-type MIS transistor. The second MIS transistor is preferably an n-type MIS transistor. Step (g) is preferably a step of forming a SiC layer as the silicon mixed-crystal layer. The first stress is preferably tensile stress.

The semiconductor device fabricating method of the aspect of the present invention preferably further comprises (m) after step (i), removing the first sidewall and the second sidewall, and (n) after (m), forming a second first-conductivity type source/drain region in a region outside the first gate electrode in the first active region, and forming a second second-conductivity type source/drain region in a region outside the second gate electrode in the second active region. The second first-conductivity type source/drain region preferably has a junction depth shallower than that of the first-conductivity type source/drain region. The second second-conductivity type source/drain region preferably has a junction depth shallower than that of the first second-conductivity type source/drain region.

As described above, according to the semiconductor device and its fabricating method according to the aspects of the present invention, when the silicon mixed-crystal layer is formed, the first insulating film formed on the first active region is used as a prevention film that prevents a silicon mixed-crystal layer from being formed on the first active region. The first insulating film functioning as this prevention film is formed before formation of the first and second outer sidewalls, so that the first insulating film on the second active region, which is formed under the second outer sidewall, can be etched. Therefore, the first insulating film remains on the second outer sidewall, i.e., an unnecessary sidewall does not remain. Therefore, the silicon mixed-crystal layer can be formed close to the channel region in the second active region, so that the first stress caused by the silicon mixed-crystal layer can be effectively applied in the gate length direction of the channel region, thereby making it possible to effectively improve the drive ability of the second MIS transistor.

In addition, even when the gap between the sidewalls formed on the side surfaces of adjacent gate electrodes becomes narrower in the second MIS transistor as miniaturization of semiconductor devices is advanced, since the first insulating film functioning as the prevention film during formation of the silicon mixed-crystal layer is formed before formation of the first and second outer sidewalls, the prevention film (protection oxide film) is not buried between the sidewalls, so that an unnecessary silicon mixed-crystal layer is not formed in the second gate electrode, as is different from the conventional art.

### BRIEF DESCRIPTION OF THE DRAWINGS

FIGS. 1A to 1D are cross-sectional views showing, in a gate length direction, major steps of a method for fabricating a semiconductor device according to a first embodiment of the present invention in order of when the steps are performed.

FIGS. 2A to 2C are cross-sectional views showing, in the gate length direction, major steps of the method for fabricating the semiconductor device of the first embodiment of the present invention in order of when the steps are performed.

FIGS. 3A to 3C are cross-sectional views showing, in the gate length direction, major steps of the method for fabricating the semiconductor device of the first embodiment of the present invention in order of when the steps are performed.

FIGS. 4A to 4C are cross-sectional views showing, in a gate length direction, major steps of a method for fabricating a semiconductor device according to a variation of the first embodiment of the present invention in order of when the steps are performed.

FIGS. 5A and 5B are cross-sectional views showing, in the gate length direction, major steps of the method for fabricating the semiconductor device of the variation of the first embodiment of the present invention in order of when the steps are performed.

FIGS. 6A to 6D are cross-sectional views showing, in a gate length direction, major steps of a method for fabricating a semiconductor device according to a second embodiment of the present invention in order of when the steps are performed.

FIGS. 7A to 7C are cross-sectional views showing, in a gate length direction, major steps of a method for fabricating a semiconductor device according to a third embodiment of the present invention in order of when the steps are performed.

FIGS. 8A and 8B are cross-sectional views showing, in the gate length direction, major steps of the method for fabricating the semiconductor device of the third embodiment of the present invention in order of when the steps are performed.

FIGS. 9A to 9C are cross-sectional views showing, in a gate length direction, major steps of a method for fabricating a semiconductor device according to a fourth embodiment of the present invention in order of when the steps are performed.

FIGS. 10A to 10C are cross-sectional views showing, in the gate length direction, major steps of the method for fabricating the semiconductor device of the fourth embodiment of the present invention in order of when the steps are performed.

FIGS. 11A to 11C are cross-sectional views showing, in the gate length direction, major steps of the method for fabricating the semiconductor device of the fourth embodiment of the present invention in order of when the steps are performed.

FIG. 12 is a cross-sectional view showing, in a gate length direction, a structure of a semiconductor device having a silicon mixed-crystal layer in a source/drain formation region of an n-type MIS transistor.

FIGS. 13A to 13D are cross-sectional views showing, in a gate length direction, major steps of a method for fabricating a conventional semiconductor device in order of when the steps are performed.

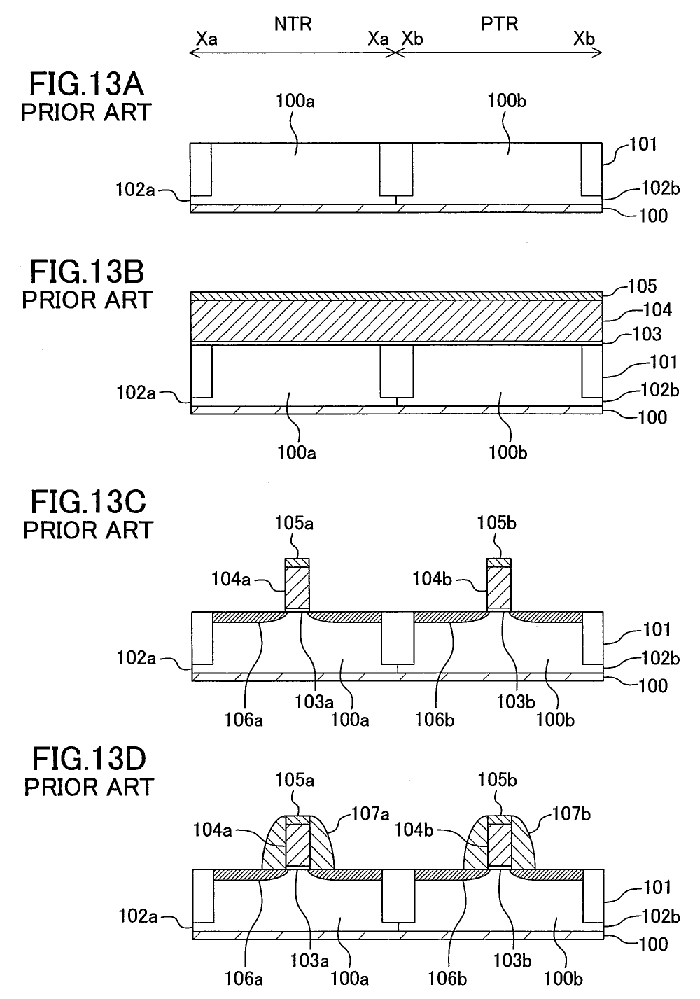

FIGS. 14A to 14C are cross-sectional views showing, in the gate length direction, major steps of the method for fabricating the conventional semiconductor device in order of when the steps are performed.

FIGS. 15A to 15C are cross-sectional views showing, in the gate length direction, major steps of the method for fabricating the conventional semiconductor device in order of when the steps are performed.

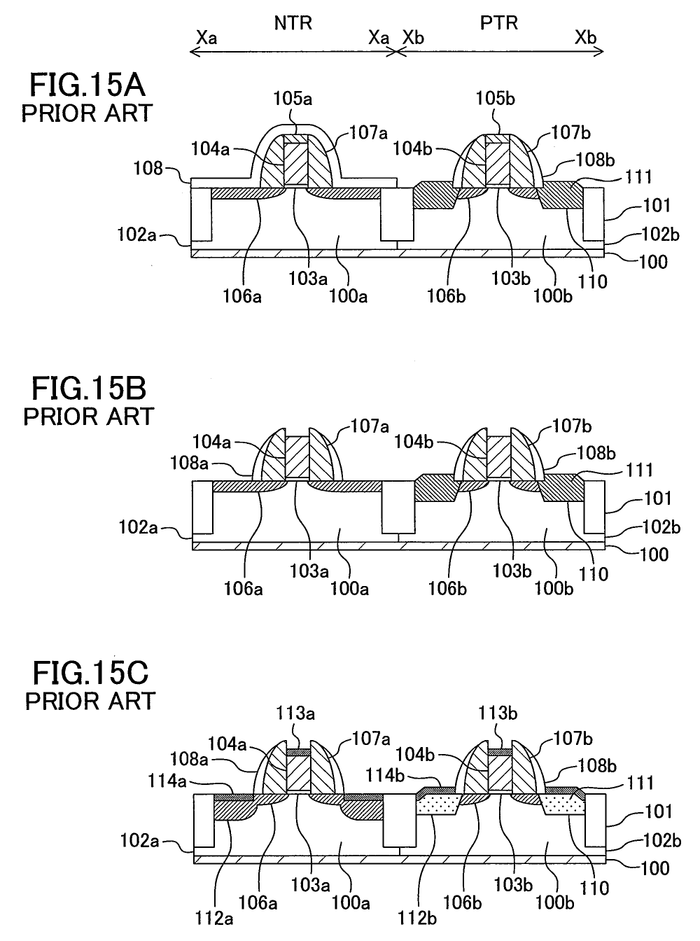

### DETAILED DESCRIPTION OF THE PREFERRED EMBODIMENTS

Hereinafter, embodiments of the present invention will be described with reference to the accompanying drawings.

### First Embodiment

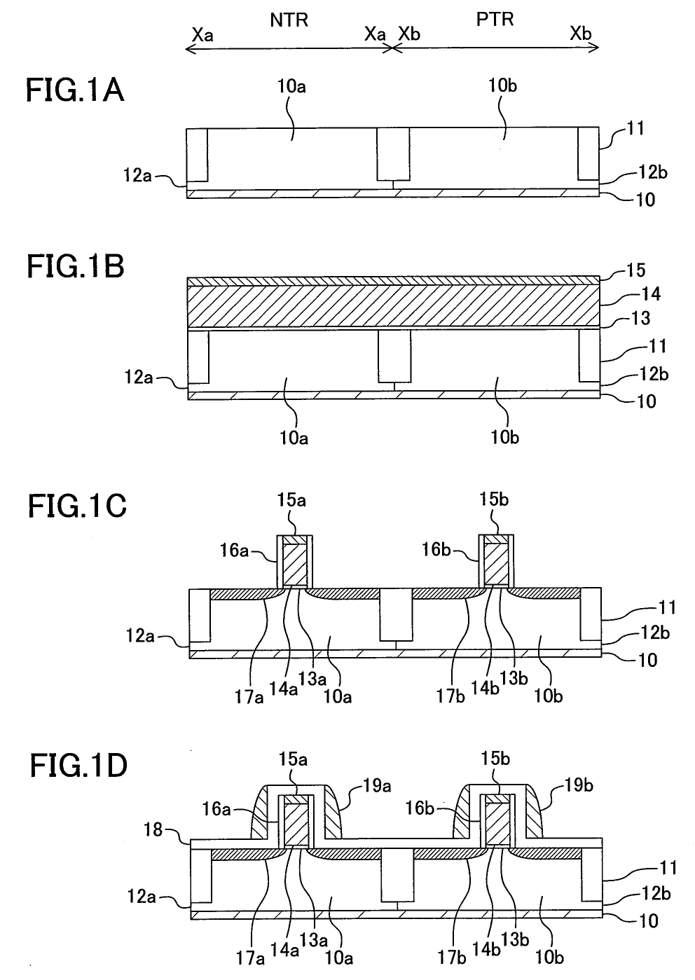

Hereinafter, a method for fabricating a semiconductor device according to a first embodiment of the present invention will be described with reference to FIGS. 1A to 1D, FIGS. 2A to 2C, and FIGS. 3A to 3C. FIGS. 1A to 1D, FIGS. 2A to 2C, and FIGS. 3A to 3C are cross-sectional views showing, in a gate length direction, major steps of the method for fabricating the semiconductor device of the first embodiment of the present invention in order of when the steps are performed. In these figures, an Xa-Xa region shown on the left-hand side indicates an n-type MIS formation region NTR, and an Xb-Xb region shown on the right-hand side indicates a p-type MIS formation region PTR.

Initially, as shown in FIG. 1A, an isolation region 11 obtained by burying an insulating film in a trench is selectively formed in an upper portion of a semiconductor substrate 10 made of, for example, p-type silicon by, for example, STI (Shallow Trench Isolation). Thereby, a first active region 10a made of the semiconductor substrate 10 surrounded by the isolation region 11 is formed in the n-type MIS formation region NTR, while a second active region 10b made of the semiconductor substrate 10 surrounded by the isolation region 11 is formed in the p-type MIS formation region PTR. Thereafter, by lithography and ion implantation, a p-type impurity, such as B (boron) or the like, is implanted into the n-type MIS formation region NTR of the semiconductor substrate 10, while an n-type impurity, such as P (phosphorus) or the like, is implanted into the p-type MIS formation region PTR of the semiconductor substrate 10. Thereafter, a heat treatment is, for example, performed at 850° C. for 30 sec so that a p-type well region 12a is formed in the n-type MIS formation region NTR of the semiconductor substrate 10, while an n-type well region 12b is formed in the p-type MIS formation region PTR of the semiconductor substrate 10.

Next, as shown in FIG. 1B, a surface of the semiconductor substrate 10 is washed by a diluted hydrogen fluoride treatment, and thereafter, a gate insulating film formation film 13 made of, for example, a silicon oxide film having a film thickness of 2 nm is formed on the first active region 10a and the second active region 10b by, for example, In-Situ Steam Generation (ISSG). Thereafter, a gate electrode formation film 14 made of, for example, a polysilicon film having a film thickness of 100 nm is deposited on the gate insulating film formation film 13 by, for example, Chemical Vapor Deposition (CVD), and thereafter, by lithography and ion implantation, an n-type impurity, such as P (phosphorus) or the like, is implanted into the gate electrode formation film 14 in the n-type MIS formation region NTR, while a p-type impurity, such as B (boron) or the like, is implanted into the gate electrode formation film 14 in the p-type MIS formation region PTR. Next, a protection film 15 made of, for example, a silicon oxide film having a film thickness of 30 nm is deposited on the gate electrode formation film 14 by, for example, CVD.

Next, as shown in FIG. 1C, the protection film 15, the gate electrode formation film 14, and the gate insulating film formation film 13 are successively subjected to patterning by photolithography and dry etching so that a first gate insulating film 13a, a first gate electrode 14a, and a first protection film 15a are formed on the first active region 10a, while a second gate insulating film 13b, a second gate electrode 14b, and a second protection film 15b are formed on the second active region 10b. Next, an offset spacer insulating film made of, for example, a silicon oxide film having a film thickness of 10 nm is deposited on an entire surface of the semiconductor substrate 10 by, for example, CVD, and thereafter, anisotropic etching is performed with respect to the offset spacer insulating film so that a first offset spacer 16a is formed on a side surface of the first gate electrode 14a, while a second offset spacer 16b is formed on a side surface of the second gate electrode 14b.

Thereafter, an n-type impurity, such as As (arsenic) or the like, is implanted into the first active region 10a by lithography and ion implantation using the first protection film 15a and the first gate electrode 14a as a mask so that an n-type source/drain region (an LDD region or an extension region) 17a having a relatively shallow junction depth is formed, in a self-aligned manner, in a region outside the first gate electrode 14a in the first active region 10a. On the other hand, a p-type impurity, such as BF₂ or the like, is implanted into the second active region 10b using the second protection film 15b and the second gate electrode 14b as a mask so that a p-type source/drain region (an LDD region or an extension region) 17b having a relatively shallow junction depth is formed, in a self-aligned manner, in a region outside the second gate electrode 14b in the second active region 10b.

Next, as shown in FIG. 1D, a first insulating film 18 made of, for example, a silicon oxide film having a film thickness of 20 nm and a second insulating film made of, for example, a silicon nitride film having a film thickness of 30 nm are successively deposited on an entire surface of the semiconductor substrate 10 by, for example, CVD, and thereafter, the second insulating film (silicon nitride film) is etched by anisotropic dry etching under etching conditions such that a selection ratio with respect to the first insulating film (silicon oxide film) 18 is set to be large. Thereby, a first outer sidewall 19a made of the second insulating film is formed on the side surface of the first gate electrode 14a with the first offset spacer 16a and the first insulating film 18 being successively interposed between the first gate electrode 14a and the first outer sidewall 19a, while a second outer sidewall 19b made of the second insulating film is formed on the side surface of the second gate electrode 14b with the second offset spacer 16b and the first insulating film 18 being successively interposed between the second gate electrode 14b and the second outer sidewall 19b. Thus, the first insulating film 18 is caused to remain, covering over the first gate electrode 14a, the first active region 10a, the second gate electrode 14b and the second active region 10b, without etching the first insulating film 18.

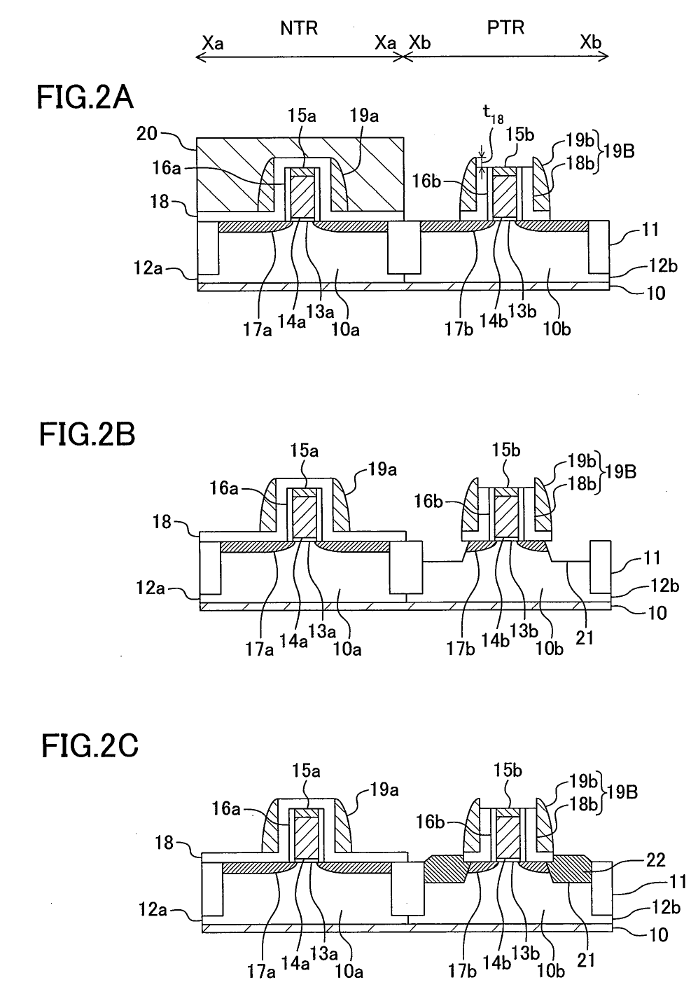

Next, as shown in FIG. 2A, a resist 20 covering the n-type MIS formation region NTR and having an opening in the p-type MIS formation region PTR is formed on the semiconductor substrate 10, and thereafter, the first insulating film (silicon oxide film) 18 formed in the p-type MIS formation region PTR is etched by anisotropic dry etching under etching conditions such that a selection ratio with respect to the second insulating film (silicon nitride film) is set to be large. Thereby, a surface of a region (source/drain formation region) outside the second outer sidewall 19b in the second active region 10b is exposed, while a second inner sidewall 18b made of the first insulating film 18 is formed. Thus, a second sidewall 19B including the second inner sidewall 18b having an L-shaped cross-section and the second outer sidewall 19b is formed on the side surface of the second gate electrode 14b with the second offset spacer 16b being interposed between the second sidewall 19B and the second gate electrode 14b.

In this case, a portion formed on an outer side of the second outer sidewall 19b and a portion formed on an inner side of the second outer sidewall 19b, of the first insulating film 18 in the p-type MIS formation region PTR, are removed. Therefore, as shown in FIG. 2A, a height of an upper end of the second inner sidewall 18b is lower by at least a film thickness (see FIG. 2A: t₁₈) of the first insulating film 18 than a height of an upper surface of the first insulating film 18 formed on the first gate electrode 14a in the n-type MIS formation region NTR.

Next, as shown in FIG. 2B, the resist 20 is removed, and thereafter, the second active region 10b whose surface is exposed is etched to a desired depth by dry etching having a selection ratio with respect to the first insulating film (silicon oxide film) and the second insulating film (silicon nitride film) or a succession of dry etching and wet etching having a selection ratio with respect to these films. Thereby, a trench 21 having a depth of, for example, 60 nm is formed in a region (i.e., the source/drain formation region) outside the second sidewall 19B in the second active region 10b of the p-type MIS formation region PTR. In this case, since a surface of the first active region 10a in the n-type MIS formation region NTR is covered with the first insulating film 18, the first active region 10a is not etched. Also, since the upper surface of the first gate electrode 14a is covered with the first protection film 15a and the first insulating film 18 successively, and the upper surface of the second gate electrode 14b is covered with the second protection film 15b, the first and second gate electrodes 14a and 14b are not etched.

Next, as shown in FIG. 2C, an etching residue, a spontaneous oxide film or the like in the trench 21 is removed by a hydrogen fluoride treatment, and thereafter, a silicon mixed-crystal layer 22 made of a p-type SiGe layer is epitaxially grown by, for example, CVD, specifically by supplying, for example, silane gas (SiH₄) and germane gas (GeH₄) along with p-type dopant gas, such as diborane gas (B₂H₆) or the like, at, for example, 650 to 700° C., so that the trench 21 is filled with the silicon mixed-crystal layer 22. In this case, since the surface of the first active region 10a in the n-type MIS formation region NTR is covered with the first insulating film 18, a SiGe layer is not epitaxially grown on the first active region 10a. Also, since the upper surface of the first gate electrode 14a is covered with the first protection film 15a and the first insulating film 18 and the upper surface of the second gate electrode 14b is covered with the second protection film 15b, a SiGe layer is not epitaxially grown on the first and second gate electrodes 14a and 14b.

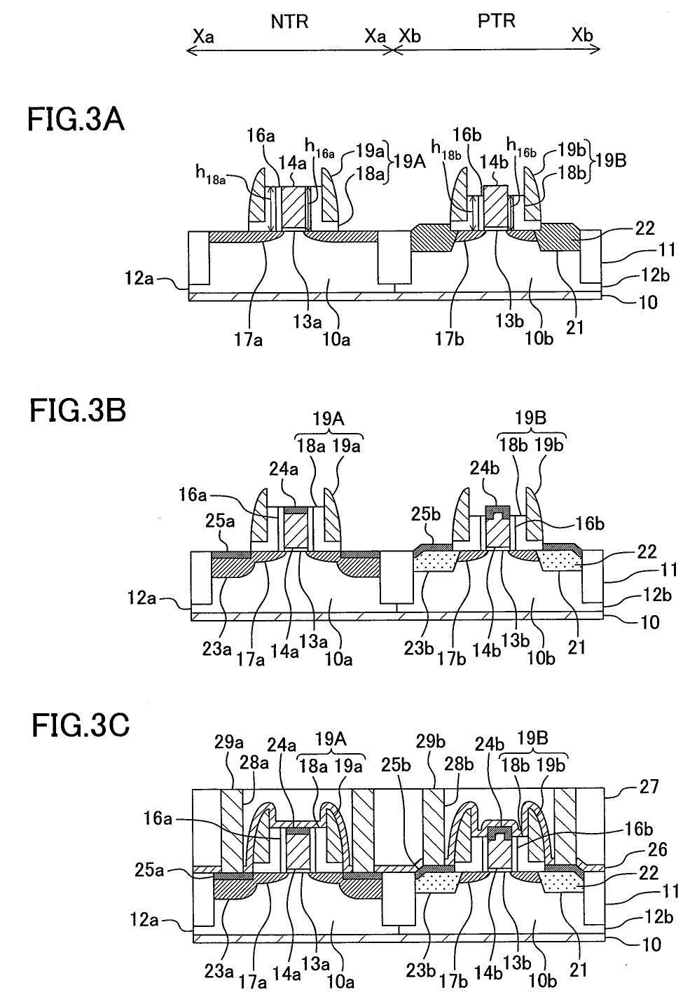

Next, as shown in FIG. 3A, in the n-type MIS formation region NTR, the first insulating film (silicon oxide film) 18 and the first protection film (silicon oxide film) 15a are etched by dry etching having a selection ratio with respect to the gate electrode formation film (polysilicon film) and the second insulating film (silicon nitride film) or a succession of dry etching and wet etching having a selection ratio with respect to these films so that a surface of a region (source/drain formation region) outside the first outer sidewall 19a in the first active region 10a and the upper surface of the first gate electrode 14a are exposed, and a first inner sidewall 18a made of the first insulating film 18 is formed. Thus, a first sidewall 19A including the first inner sidewall 18a having an L-shaped cross-section and the first outer sidewall 19a is formed on the side surface of the first gate electrode 14a with the first offset spacer 16a being interposed between the first sidewall 19A and the first gate electrode 14a. On the other hand, in the p-type MIS formation region PTR, the second protection film (silicon oxide film) 15b is etched so that the upper surface of the second gate electrode 14b is exposed. Thus, etching in the step of FIG. 3A is performed until the upper surface of the first gate electrode 14a, the surface of the first active region 10a (specifically, the surface of the source/drain formation region), and the upper surface of the second gate electrode 14b are exposed.

In this case, not only the first insulating film (silicon oxide film) 18 in the n-type MIS formation region NTR and the first and second protection films (silicon oxide films) 15a and 15b, but also the first and second offset spacers (silicon oxide films) 16a and 16b and the second inner sidewall (silicon oxide film) 18b that are made of the same material as that for those films (18, 15a and 15b), are also etched.

Here, in the previous step, i.e., the step of FIG. 2C, the upper end height of the second inner sidewall 18b in the p-type MIS formation region PTR is lower by at least the film thickness of the first insulating film 18 (see FIG. 2A: t₁₈) than the upper surface height of the first insulating film 18 formed on the first gate electrode 14a in the n-type MIS formation region NTR. Also, both the upper surface of the first insulating film 18 and the upper end of the second inner sidewall 18b are exposed. Therefore, in the step of FIG. 3A, both the exposed first insulating film 18 and second inner sidewall 18b are etched for the same etching time. Therefore, as shown in FIG. 3A, a height h_{18b} of an upper end of the second inner sidewall 18b is maintained lower by at least a film thickness of the first inner sidewall 18a than a height h₁₈ₐ of an upper end of the first inner sidewall 18a made of the first insulating film 18.

Also, here, in the previous step, i.e., the step of FIG. 2C, a height of an upper end of the first offset spacer 16a is substantially the same as a height of an upper end of the second offset spacer 16b. Also, the first insulating film 18 is formed on the first offset spacer 16a, so that the upper end of the first offset spacer 16a is not exposed. By contrast, the upper end of the second offset spacer 16b is exposed. Therefore, in the step of FIG. 3A, the second offset spacer 16b whose upper end is exposed is etched for a longer time by at least the etching time of the first insulating film 18 than that of the first offset spacer 16a whose upper end is covered with the first insulating film 18. Therefore, a height h_{16b} of the upper end of the second offset spacer 16b is lower by at least the film thickness of the first inner sidewall 18a than a height h₁₆ₐ of the upper end of the first offset spacer 16a.

Thus, as shown in FIG. 3A, the upper end height h_{18b} of the second inner sidewall 18b is lower by at least the film thickness of the first inner sidewall 18a than the upper end height h₁₈ₐ of the first inner sidewall 18a. Also, the upper end height h_{16b} of the second offset spacer 16b is lower by at least the film thickness of the first inner sidewall 18a than the upper end height h₁₆ₐ of the first offset spacer 16a. Therefore, the upper surface of the second gate electrode 14b protrudes above the upper ends of the second offset spacer 16b and the second inner sidewall 18b.

Next, as shown in FIG. 3B, an n-type impurity, such as As (arsenic) or the like, is implanted into the first active region 10a by lithography and ion implantation using the first gate electrode 14a, the first offset spacer 16a and the first sidewall 19A as a mask so that an n-type source/drain region 23a having a relatively deep junction depth is formed, in a self-aligned manner, in a region outside the first sidewall 19A of the first active region 10a. On the other hand, a p-type impurity, such as B (boron) or the like, is implanted into the second active region 10b using the second gate electrode 14b, the second offset spacer 16b and the second sidewall 19B as a mask so that a p-type source/drain region 23b having a relatively deep junction depth is formed, in a self-aligned manner, in a region of the silicon mixed-crystal layer 22 outside the second sidewall 19B in the second active region 10b. Thereafter, the impurities contained in the deep n-type source/drain region 23a and the deep p-type source/drain region 23b are activated by a heat treatment.

Next, a spontaneous oxide film (not shown) formed on the first and second gate electrodes 14a and 14b and the deep n-type source/drain region 23a and the deep p-type source/drain region 23b is removed, and thereafter, a metal film (not shown) made of, for example, nickel having a film thickness of 10 nm is deposited on an entire surface of the semiconductor substrate 10 by, for example, sputtering. Thereafter, for example, by the first Rapid Thermal Annealing (RTA) treatment in an atmosphere of nitrogen at 320° C., Si of the first and second gate electrodes 14a and 14b and Ni of the metal film are caused to react with each other so that first and second silicide layers 24a and 24b made of a nickel silicide film are formed in upper portions of the first and second gate electrodes 14a and 14b, and in addition, Si of the deep n-type source/drain region 23a and the deep p-type source/drain region 23b and Ni of the metal film are caused to react with each other so that third and fourth silicide layers 25a and 25b made of a nickel silicide film are formed in upper portions of the deep n-type source/drain region 23a and the deep p-type source/drain region 23b.

In this case, in the previous step, i.e., the step of FIG. 3A, the upper surface of the first gate electrode 14a has substantially the same height as that of the upper ends of the first offset spacer 16a and the first inner sidewall 18a. By contrast, the upper surface of the second gate electrode 14b protrudes above the upper ends of the second offset spacer 16b and the second inner sidewall 18b. Therefore, in the step of FIG. 3B, the first gate electrode 14a is subjected to the heat treatment with only the upper surface thereof being in contact with the silicidation metal film, so that a metal is supplied from the silicidation metal film that is in contact only with the upper surface, whereas the second gate electrode 14b is subjected to the heat treatment with the side surface thereof as well as the upper surface thereof being in contact with the silicidation metal film, so that a metal is supplied from the silicidation metal film that is in contact with the side surface as well as from the silicidation metal film that is in contact with the upper surface. Therefore, the second silicide layer 24b has a larger film thickness than that of the first silicide layer 24a.

Thereafter, the semiconductor substrate 10 is immersed in an etching solution including sulfuric acid and hydrogen peroxide water, thereby removing an unreacted metal film remaining on the isolation region 11, the first and second offset spacers 16a and 16b, the first and second sidewalls 19A and 19B, and the like. Thereafter, the silicide composition ratios of the first and second silicide layers 24a and 24b and the third and fourth silicide layers 25a and 25b are made stable by the second RTA treatment at a temperature (e.g., 550° C.) higher than that of the first RTA treatment.

Thus, a CMIS element in which a silicon mixed-crystal layer is not provided in the source/drain formation region of the n-type MIS transistor, and a silicon mixed-crystal layer is provided only in the source/drain formation region of the p-type MIS transistor, is formed.

Next, as shown in FIG. 3C, an underlying insulating film 26 made of, for example, a silicon nitride film is formed on an entire surface of the semiconductor substrate 10, covering the first active region 10a and the second active region 10b. Thereafter, an interlayer insulating film 27 made of, for example, a silicon oxide film is formed on the underlying insulating film 26, and thereafter, planarization is performed with respect to a surface of the interlayer insulating film 27 by CMP. Thereafter, a resist having an opening (not shown) in a contact hole formation region is formed on the interlayer insulating film 27. Thereafter, using the resist as a mask, a hole reaching an upper surface of the underlying insulating film 26 is formed in the interlayer insulating film 27 by the first dry etching. Thereafter, a portion exposed in the hole of the underlying insulating film 26 is removed by the second dry etching so that first and second contact holes 28a and 28b reaching upper surfaces of the third and fourth silicide layers 25a and 25b are formed in the underlying insulating film 26 and the interlayer insulating film 27. Thus, the amount of overetching with respect to the third and fourth silicide layers 25a and 25b can be reduced by two-step etching.

Thereafter, a barrier metal film including a titanium film and a nitride titanium film that are successively laminated is formed at bottom portions and sidewall portions of the first and second contact holes 28a and 28b by sputtering or CVD. Thereafter, a tungsten film is deposited on the interlayer insulating film 27 by CVD so that the first and second contact holes 28a and 28b are filled with the tungsten film, and thereafter, a portion of the tungsten film that is formed outside the first and second contact holes 28a and 28b is removed by CMP. Thus, first and second contact plugs 29a and 29b made of the tungsten film are formed in the first and second contact holes 28a and 28b with the barrier metal film being interposed between the first and second contact plugs 29a and 29b and the first and second contact holes 28a and 28b. Thereafter, a metal wire (not shown) for electrically connecting the first and second contact plugs 29a and 29b is formed on the interlayer insulating film 27.

The semiconductor device of this embodiment can be thus fabricated.

Hereinafter, a structure of the semiconductor device of the first embodiment of the present invention will be described with reference to FIG. 3C.

As shown in FIG. 3C, the semiconductor device comprises the n-type MIS transistor provided in the n-type MIS formation region NTR and the p-type MIS transistor provided in the p-type MIS formation region PTR.

Here, as shown in FIG. 3C, the n-type MIS transistor comprises the first active region 10a surrounded by the isolation region 11 in the semiconductor substrate 10, the first gate insulating film 13a formed on the first active region 10a, the first gate electrode 14a formed on the first gate insulating film 13a, the first offset spacer 16a formed on the side surface of the first gate electrode 14a, the first sidewall 19A including the first inner sidewall 18a having an L-shaped cross-section and the first outer sidewall 19a formed on the side surface of the first gate electrode 14a with the first offset spacer 16a being interposed between the first inner sidewall 18a and the first gate electrode 14a, the n-type source/drain region 17a having a relatively shallow junction depth formed in a region outside the first gate electrode 14a in the first active region 10a, the n-type source/drain region 23a having a relatively deep junction depth formed in a region outside the first sidewall 19A in the first active region 10a, the first silicide layer 24a formed on the first gate electrode 14a, and the third silicide layer 25a formed on the deep n-type source/drain region 23a.

On the other hand, as shown in FIG. 3C, the p-type MIS transistor comprises the second active region 10b surrounded by the isolation region 11 in the semiconductor substrate 10, the second gate insulating film 13b formed on the second active region 10b, the second gate electrode 14b formed on the second gate insulating film 13b, the second offset spacer 16b formed on the side surface of the second gate electrode 14b, the second sidewall 19B including the second inner sidewall 18b having an L-shaped cross-section and the second outer sidewall 19b formed on the side surface of the second gate electrode 14b with the second offset spacer 16b being interposed between the second inner sidewall 18b and the second gate electrode 14b, the silicon mixed-crystal layer 22 formed in the trench 21 provided in a region outside the second sidewall 19B in the second active region 10b, that causes compressive stress in the gate length direction of the channel region in the second active region 10b, the p-type source/drain region 17b having a relatively shallow junction depth formed in a region outside the second gate electrode 14b in the second active region 10b, the p-type source/drain region 23b having a relatively deep junction depth formed in a region including the silicon mixed-crystal layer 22 outside the second sidewall 19B in the second active region 10b, the second silicide layer 24b formed on the second gate electrode 14b, and the fourth silicide layer 25b formed on the deep p-type source/drain region 23b.

Further, the underlying insulating film 26 and the interlayer insulating film 27 are successively formed on the semiconductor substrate 10, and the first and second contact plugs 29a and 29b that electrically connect the deep source/drain regions 23a and 23b are formed in the underlying insulating film 26 and the interlayer insulating film 27 with the third and fourth silicide layers 25a and 25b being interposed between the first and second contact plugs 29a and 29b and the deep source/drain regions 23a and 23b.

Thus, in the semiconductor device of this embodiment, the upper end height of the second inner sidewall 18b is lower by at least the film thickness of the first inner sidewall 18a than the upper end height of the first inner sidewall 18a. Also, the upper end height of the second offset spacer 16b is lower by at least the film thickness of the first inner sidewall 18a than the upper end height of the first offset spacer 16a. The second silicide layer 24b has a larger film thickness than that of the first silicide layer 24a.

According to this embodiment, when the silicon mixed-crystal layer 22 made of a SiGe layer is epitaxially grown in the trench 21 provided in the second active region 10b of the p-type MIS formation region PTR, the first insulating film 18 formed in the n-type MIS formation region NTR is used as an epitaxial growth preventing film that prevents a SiGe layer from being epitaxially grown on the first active region 10a in the n-type MIS formation region NTR, as shown in FIG. 2C.

Since the first insulating film 18 functioning as an epitaxial growth preventing film is formed before formation of the first and second outer sidewalls 19a and 19b (see FIG. 1D), etching can be performed while the first insulating film 18 in the p-type MIS formation region PTR is formed under the second outer sidewall 19b as shown in FIG. 2A, so that the first insulating film 18 does not remain on the second outer sidewall 19b.

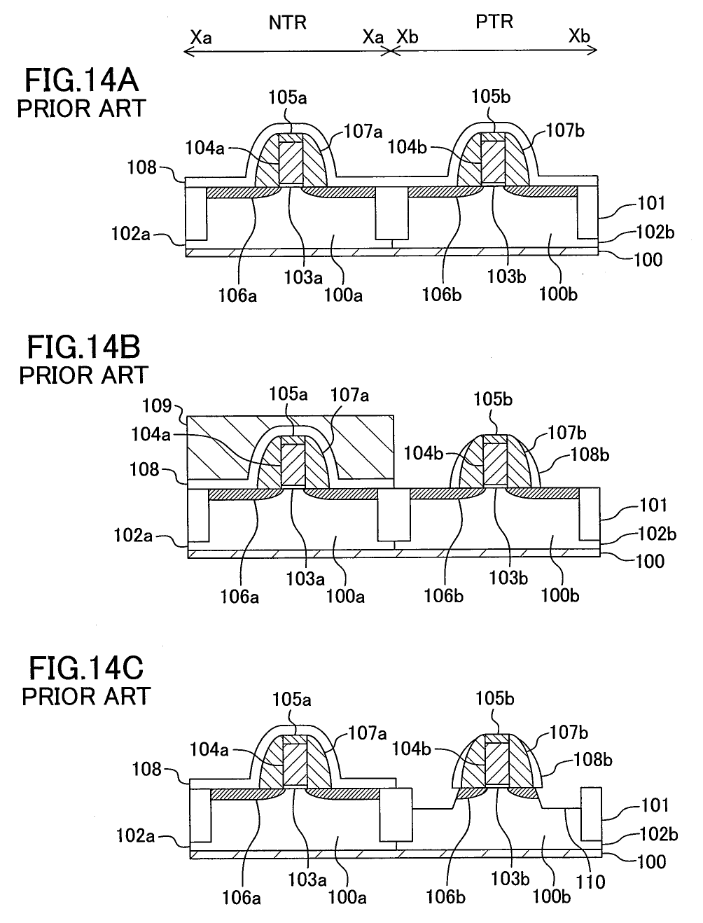

In other words, it is possible to avoid the conventional situation in which the protection oxide film 108 functioning as an epitaxial growth preventing film is formed after formation of the first and second sidewalls 107a and 107b (see FIG. 14A described above), so that, as shown in FIG. 14B, etching is performed while the protection oxide film 108 in the p-type MIS formation region PTR is formed on the second sidewall 107b, whereby the unnecessary sidewall 108b does not remain on the second sidewall 107b.

Therefore, as is different from the conventional art, the silicon mixed-crystal layer 111 can be prevented from being formed at a distance from the channel region of the p-type MIS transistor due to the remainder of the unnecessary sidewall 108b. Therefore, the silicon mixed-crystal layer 22 can be formed close to the channel region. Thereby, compressive stress caused by the silicon mixed-crystal layer 22 can be effectively applied in the gate length direction of the channel region, thereby making it possible to effectively improve the drive ability of the p-type MIS transistor.

In addition, even when the gap between sidewalls formed on the side surfaces of adjacent gate electrodes becomes narrower in the p-type MIS transistor as miniaturization of semiconductor devices is advanced, since the first insulating film 18 functioning as an epitaxial growth preventing film is formed before formation of the first and second outer sidewalls 19a and 19b (see FIG. 1D), the epitaxial growth preventing film (protection oxide film) 108 is not buried between the sidewalls, so that an unnecessary SiGe layer is not formed in the second gate electrode 14b, as is different from the conventional art.

Thus, the silicon mixed-crystal layer 22 can be formed only in the source/drain formation region of the p-type MIS transistor with accuracy.

Moreover, in the step of FIG. 2C, the first insulating film 18 not only functions as an epitaxial growth preventing film, but also becomes the second inner sidewall 18b (see FIG. 2A) to form a portion of the second sidewall 19B, and becomes the first inner sidewall 18a (see FIG. 3A) to form a portion of the first sidewall 19A. Therefore, as is different from the conventional art, the protection oxide film 108 functioning as an epitaxial growth preventing film does not need to be additionally formed, so that the number of steps can be reduced. In addition, it is possible to avoid the conventional situation in which the protection oxide film 108 cannot be perfectly removed, so that the fourth sidewall 108b made of the protection oxide film 108 remains, leading to a defect due to the remainder of the unnecessary sidewall 108b.

Although a metal film made of nickel is used as a silicidation metal film when the first and second silicide layers 24a and 24b and the third and fourth silicide layers 25a and 25b are formed, a silicidation metal, such as platinum, cobalt, titanium, tungsten or the like, may be used instead of this.

### Variation of First Embodiment

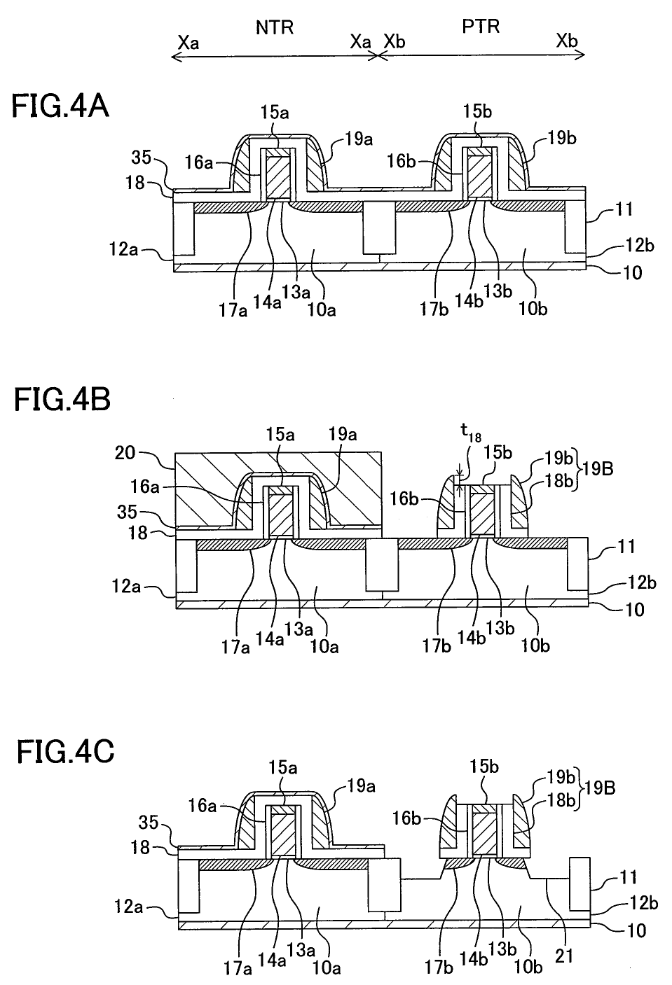

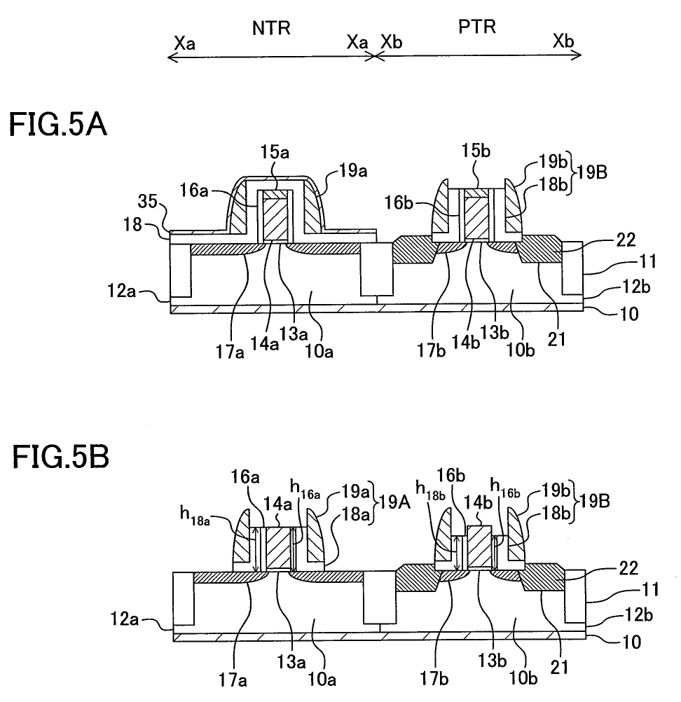

Hereinafter, a method for fabricating a semiconductor device according to a variation of the first embodiment of the present invention will be described with reference to FIGS. 4A to 4C and FIGS. 5A and 5B. FIGS. 4A to 4C and FIGS. 5A and 5B are cross-sectional views showing, in a gate length direction, major steps of the method for fabricating the semiconductor device of the variation of the first embodiment of the present invention in order of when the steps are performed. In these figures, an Xa-Xa region shown on the left-hand side indicates an n-type MIS formation region NTR, and an Xb-Xb region shown on the right-hand side indicates a p-type MIS formation region PTR. Here, in FIGS. 4A to 4C and FIGS. 5A and 5B, the same parts as those of the semiconductor device of the first embodiment are indicated by the same reference symbols and will not be described in detail.

Initially, the steps of FIGS. 1A to 1D of the first embodiment are successively performed, thereby obtaining the structure of FIG. 1D. Note that the film thickness of the first insulating film 18 is assumed to be 15 nm.

Next, as shown in FIG. 4A, a surface protection film 35 made of, for example, a silicon oxide film having a film thickness of 5 nm is deposited on an entire surface of a semiconductor substrate 10 by, for example, CVD.

Next, as shown in FIG. 4B, a resist 20 covering the n-type MIS formation region NTR and having an opening in the p-type MIS formation region PTR is formed on the semiconductor substrate 10, and thereafter, the surface protection film 35 formed in the p-type MIS formation region PTR is removed by wet etching or isotropic dry etching.

Thereafter, the first insulating film (silicon oxide film) 18 formed in the p-type MIS formation region PTR is etched by a step similar to that of FIG. 2A. Thereby, a surface of a region (source/drain formation region) outside a second outer sidewall 19b in a second active region 10b is exposed, and a second inner sidewall 18b made of the first insulating film 18 is formed. Thus, a second sidewall 19B including the second inner sidewall 18b having an L-shaped cross-section and the second outer sidewall 19b is formed on a side surface of a second gate electrode 14b with a second offset spacer 16b being interposed between the second sidewall 19B and the second gate electrode 14b. In this case, as shown in FIG. 4B, a height of an upper end of the second inner sidewall 18b is lower by at least a film thickness of the first insulating film 18 (see FIG. 4B: t₁₈) than a height of an upper surface of the first insulating film 18 formed on the first gate electrode 14a in the n-type MIS formation region NTR.

Next, as shown in FIG. 4C, the resist 20 is removed, and thereafter, the second active region 10b whose surface is exposed is etched to a desired depth by a step similar to that of FIG. 2B, so that a trench 21 having a depth of, for example, 60 nm is formed in a region, i.e., a source/drain formation region, outside the second sidewall 19B in the p-type MIS formation region PTR of the second active region 10b.

Next, as shown in FIG. 5A, a silicon mixed-crystal layer 22 made of a p-type SiGe layer is epitaxially grown by a step similar to that of FIG. 2C so that the trench 21 is filled with the silicon mixed-crystal layer 22.

Next, as shown in FIG. 5B, the surface protection film (silicon oxide film) 35, the first insulating film (silicon oxide film) 18, and a first protection film (silicon oxide film) 15a in the n-type MIS formation region NTR are etched by dry etching having a selection ratio with respect to a gate electrode formation film (polysilicon film) and a second insulating film (silicon nitride film) or a succession of dry etching and wet etching having a selection ratio with respect to these films, so that a surface of a region (source/drain formation region) outside the first outer sidewall 19a in the first active region 10a and an upper surface of the first gate electrode 14a are exposed and a first inner sidewall 18a made of the first insulating film 18 is formed. Thus, a first sidewall 19A including the first inner sidewall 18a having an L-shaped cross-section and the first outer sidewall 19a is formed on a side surface of the first gate electrode 14a with the first offset spacer 16a being interposed between the first sidewall 19A and the first gate electrode 14a. On the other hand, in the p-type MIS formation region PTR, a second protection film (silicon oxide film) 15b is etched to expose an upper surface of the second gate electrode 14b.

Here, the state of the previous step, i.e., the step of FIG. 5A, is different from the state of FIG. 2C of the first embodiment in that the surface protection film 35 is additionally formed on the semiconductor substrate 10 in the n-type MIS formation region NTR. Therefore, as shown in FIG. 5B, an upper end height h_{18b} of the second inner sidewall 18b is lower by at least the total sum of a film thickness of the surface protection film 35 and a film thickness of the first inner sidewall 18a than an upper end height h₁₈ₐ of the first inner sidewall 18a. Also, an upper end height h_{16b} of the second offset spacer 16b is lower by at least the total sum of the film thickness of the surface protection film 35 and the film thickness of the first inner sidewall 18a than an upper end height h₁₆ₐ of the first offset spacer 16a. Therefore, the upper surface of the second gate electrode 14b protrudes above the upper ends of the second offset spacer 16b and the second inner sidewall 18b.

Next, steps similar to those of FIGS. 3B and 3C of the first embodiment are successively performed to form an underlying insulating film, an interlayer insulating film, a contact plug and the like on the semiconductor substrate 10, thereby obtaining a structure as shown in FIG. 3C.

According to this variation, an effect similar to that of the first embodiment can be obtained.

In addition, in the step of FIG. 5A, by using a multilayer film including the first insulating film (silicon oxide film) 18 having a film thickness of 15 nm and the surface protection film (silicon oxide film) 35 having a film thickness of 5 nm as an epitaxial growth preventing film, the silicon oxide film having a film thickness of 20 nm can be used as an epitaxial growth preventing film as in the first embodiment (see FIG. 2C). Therefore, as in the first embodiment, the thickness of the first insulating film 18 can be reduced while preventing a SiGe layer from being epitaxially grown on the first active region 10a. Therefore, the film thicknesses of the first and second inner sidewalls 18a and 18b of this variation can be made smaller than the film thicknesses of the first and second inner sidewalls 18a and 18b of the first embodiment, so that the size of the semiconductor device can be reduced.

Thus, according to this variation, an effect similar to that of the first embodiment can be obtained, and in addition, the film thicknesses of the first and second inner sidewalls 18a and 18b can be reduced. Therefore, this variation is particularly effective to miniaturization of a semiconductor device.

### Second Embodiment

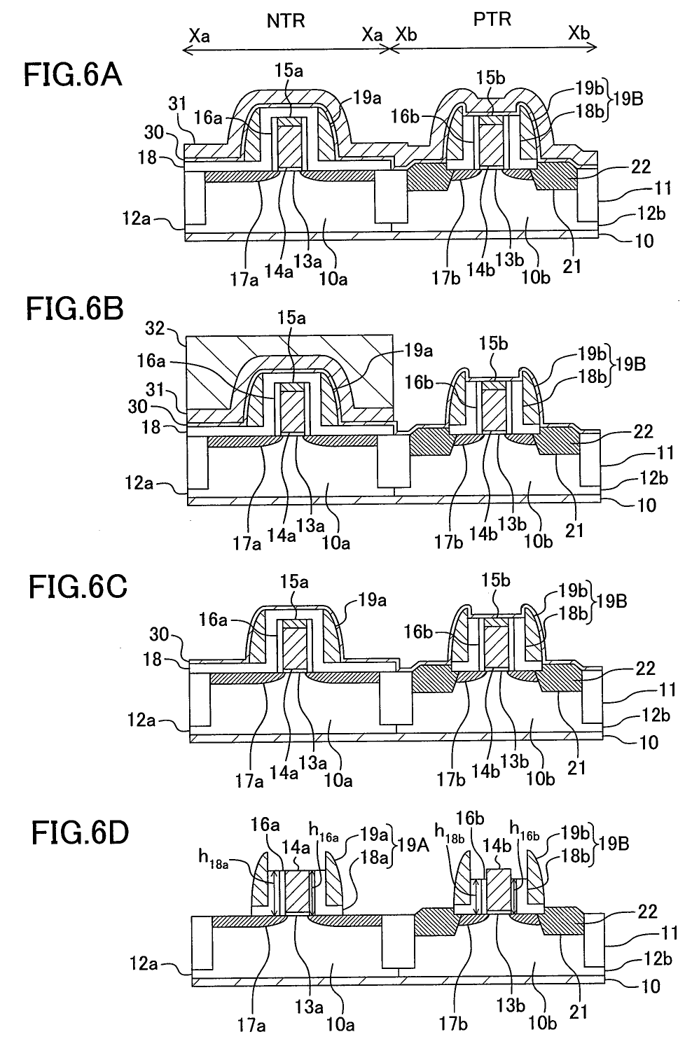

Hereinafter, a method for fabricating a semiconductor device according to a second embodiment of the present invention will be described with reference to FIGS. 6A to 6D. FIGS. 6A to 6D are cross-sectional views showing, in a gate length direction, major steps of the method for fabricating the semiconductor device of the second embodiment of the present invention in order of when the steps are performed. In these figures, an Xa-Xa region shown on the left-hand side indicates an n-type MIS formation region NTR, and an Xb-Xb region shown on the right-hand side indicates a p-type MIS formation region PTR. Here, in FIGS. 6A to 6D, the same parts as those of the semiconductor device of the first embodiment are indicated by the same reference symbols and will not be described in detail.

Here, the fabricating method of this embodiment has the following features.

In this embodiment, after the steps of FIGS. 1A to 1D and FIGS. 2A to 2C are successively performed as in the first embodiment, a step of memorizing tensile stress in the gate length direction of a channel region in the first active region 10a is further performed by SMT using a stressor insulating film 31 as shown in FIGS. 6A to 6C, and thereafter, a step shown in FIG. 6D corresponding to the step of FIG. 3A of the first embodiment is performed before steps similar to the steps of FIGS. 3B and 3C of the first embodiment are successively performed.

Initially, the steps of FIGS. 1A to 1D and FIGS. 2A to 2C of the first embodiment are successively performed to obtain the structure of FIG. 2C.

Next, as shown in FIG. 6A, for example, an underlying protection film 30 made of a silicon oxide film having a film thickness of 10 nm and a stressor insulating film 31 made of a silicon nitride film having a film thickness of 40 nm that has tensile stress are successively deposited on an entire surface of the semiconductor substrate 10 by, for example, CVD.

Next, as shown in FIG. 6B, a resist 32 covering the n-type MIS formation region NTR and having an opening in the p-type MIS formation region PTR are formed on the semiconductor substrate 10, and thereafter, the stressor insulating film (silicon nitride film) 31 formed in the p-type MIS formation region PTR is removed by dry etching or wet etching under etching conditions such that a selection ratio with respect to the underlying protection film (silicon oxide film) 30 is set to be large, thereby exposing a surface of the underlying protection film 30 in the p-type MIS formation region PTR. Next, the resist 32 is removed, and thereafter, the semiconductor substrate 10 is subjected to a spike RTA treatment at a temperature of, for example, 1050° C. In this case, tensile stress is applied in a gate length direction of the first gate electrode 14a and a channel region in the first active region 10a by a Stress Memorization Technique (SMT) using the stressor insulating film 31, so that the state of polysilicon crystal of the first gate electrode 14a and the state of silicon crystal of the first active region 10a are changed. Thereby, the first gate electrode 14a has an average grain size of polysilicon film (crystal grain size) larger than that of the second gate electrode 14b, and tensile stress is memorized in the gate length direction of the channel region in the first active region 10a.

Next, as shown in FIG. 6C, the stressor insulating film (silicon nitride film) 31 formed in the n-type MIS formation region NTR is removed by dry etching or wet etching under etching conditions such that a selection ratio with respect to the underlying protection film (silicon oxide film) 30 is set to be large, thereby exposing a surface of the underlying protection film 30 in the n-type MIS formation region NTR. In this case, even after removal of the stressor insulating film 31, tensile stress is maintained in the memorized state in the gate length direction of the channel region in the first active region 10a.

Next, as shown in FIG. 6D, the underlying protection film (silicon oxide film) 30, the first insulating film (silicon oxide film) 18, and the first protection film (silicon oxide film) 15a are etched in the n-type MIS formation region NTR by dry etching having a selection ratio with respect to the gate electrode formation film (polysilicon film) and the second insulating film (silicon nitride film) or a succession of dry etching and wet etching having a selection ratio with respect to these films, so that a surface in a region outside the first outer sidewall 19a in the first active region 10a and an upper surface of the first gate electrode 14a are exposed and a first inner sidewall 18a made of the first insulating film 18 is formed. Thus, a first sidewall 19A including the first inner sidewall 18a having an L-shaped cross-section and the first outer sidewall 19a is formed on a side surface of the first gate electrode 14a with the first offset spacer 16a being interposed between the first sidewall 19A and the first gate electrode 14a. On the other hand, in the p-type MIS formation region PTR, the underlying protection film (silicon oxide film) 30 and the second protection film (silicon oxide film) 15b are etched so that a surface of the silicon mixed-crystal layer 22 and an upper surface of the second gate electrode 14b are exposed.

In this case, the state of FIG. 6C (previous step) is different from the state of FIG. 2C in the first embodiment only in that the underlying protection film (silicon oxide film) 30 is additionally formed on the entire surface of the semiconductor substrate 10. Therefore, in the step of FIG. 6D, etching after removal of the underlying protection film 30 is similar to etching in the step of FIG. 3A of the first embodiment, so that the structure of FIG. 6D is similar to that of FIG. 3A. Specifically, as shown in FIG. 6D, an upper end height h_{18b} of the second inner sidewall 18b is lower by at least a film thickness of the first inner sidewall 18a than an upper end height h₁₈ₐ of the first inner sidewall 18a. Also, an upper end height h_{16b} of the second offset spacer 16b is lower by at least the film thickness of first inner sidewall 18a than an upper end height h₁₆ₐ of the first offset spacer 16a.

Next, steps similar to those of FIGS. 3B and 3C of the first embodiment are successively performed so that an underlying insulating film, an interlayer insulating film, a contact plug and the like are formed on the semiconductor substrate 10, thereby obtaining a structure as shown in FIG. 3C.

According to this embodiment, an effect similar to that of the first embodiment can be obtained.

In addition, tensile stress is applied in the gate length direction of the channel region in the n-type MIS transistor by performing the step of memorizing tensile stress in the gate length direction of the channel region in the first active region 10a (see FIGS. 6A to 6C) between the step of FIG. 2C and the step of FIG. 6D (a step corresponding to the step of FIG. 3A of the first embodiment), so that the mobility of electrons is increased, resulting in an improvement in the drive ability of the n-type MIS transistor.

Thus, in this embodiment, as in the first embodiment, compressive stress is effectively applied in the gate length direction of the channel region in the second active region 10b by the silicon mixed-crystal layer 22, thereby effectively improving the drive ability of the p-type MIS transistor. In addition, tensile stress is memorized in the gate length direction of the channel region in the first active region 10a by SMT, thereby making it possible to improve the drive ability of the n-type MIS transistor.

### Third Embodiment

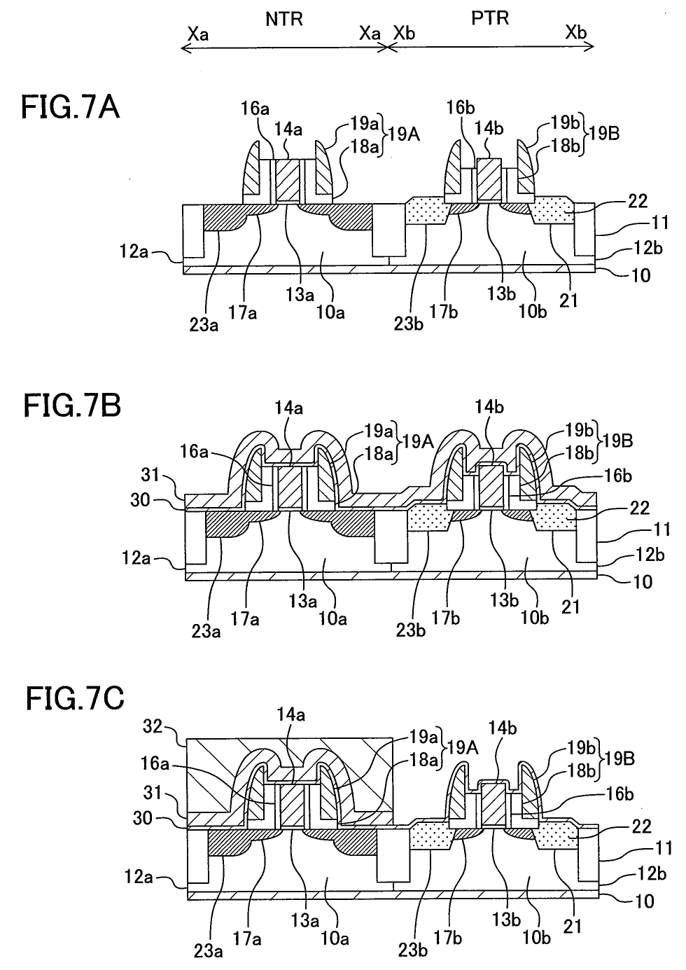

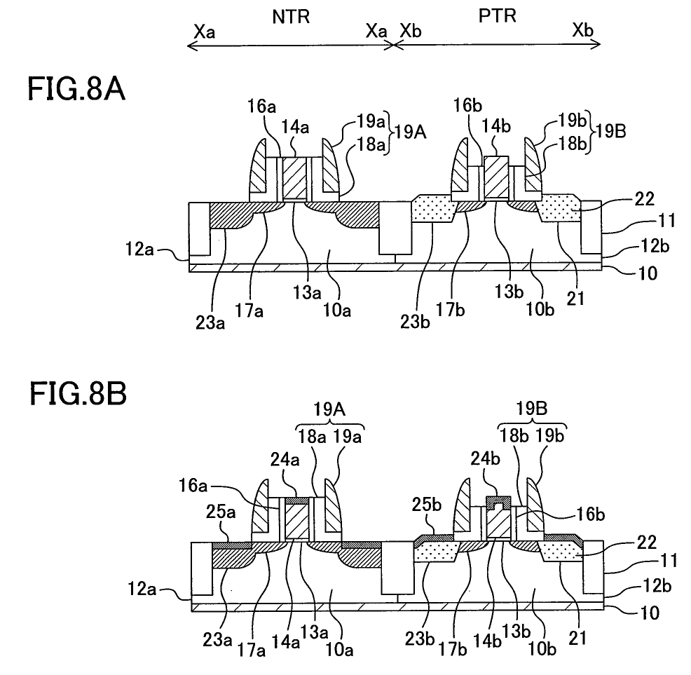

Hereinafter, a method for fabricating a semiconductor device according to a third embodiment of the present invention will be described with reference to FIGS. 7A to 7C and FIGS. 8A and 8B. FIGS. 7A to 7C and FIGS. 8A and 8B are cross-sectional views showing, in a gate length direction, major steps of the method for fabricating the semiconductor device of the third embodiment of the present invention in order of when the steps are performed. In these figures, an Xa-Xa region shown on the left-hand side indicates an n-type MIS formation region NTR, and an Xb-Xb region shown on the right-hand side indicates a p-type MIS formation region PTR. Here, in FIGS. 7A to 7C and FIGS. 8A and 8B, the same parts as those of the semiconductor device of the first embodiment are indicated by the same reference symbols and will not be described in detail.

Here, this embodiment is different from the second embodiment in terms of the fabricating method in the following points.

In the second embodiment, after the steps of FIGS. 1A to 1D and FIGS. 2A to 2C are successively performed, the step of memorizing tensile stress in the gate length direction of the channel region in the first active region 10a is further performed, and thereafter, as shown in FIG. 6D, the first inner sidewall 18a is formed by etching before formation of the deep n-type source/drain region 23a and the deep p-type source/drain region 23b as in the step of FIG. 3B in the first embodiment. By contrast, in this embodiment, after the steps of FIGS. 1A to 1D and FIGS. 2A to 2C are successively performed, the first inner sidewall 18a is formed by etching as in FIG. 3A, and thereafter, the deep n-type source/drain region 23a and the deep p-type source/drain region 23b are formed as shown in FIG. 7A, and thereafter, a step of memorizing tensile stress in the gate length direction of the channel region in the first active region 10a is performed as shown in FIGS. 7B and 7C and FIG. 8A.

Thus, in the third embodiment, the deep n-type source/drain region 23a and the deep p-type source/drain region 23b are formed (see FIG. 7A) before tensile stress is memorized in the gate length direction of the channel region in the first active region 10a (see FIGS. 7B and 7C and FIG. 8A).

Initially, the steps of FIGS. 1A to 1D, FIGS. 2A to 2C, and FIG. 3A of the first embodiment are successively performed to obtain the structure of FIG. 3A. Specifically, the upper surface of the second gate electrode 14b protrudes above the upper ends of the second offset spacer 16b and the second inner sidewall 18b.

Next, as shown in FIG. 7A, an n-type impurity, such as As (arsenic) or the like, is implanted into the first active region 10a by lithography and ion implantation using the first gate electrode 14a, the first offset spacer 16a, and the first sidewall 19A as a mask, thereby forming, in a self-aligned manner, an n-type source/drain region 23a having a relatively deep junction depth in a region outside the first sidewall 19A in the first active region 10a. On the other hand, a p-type impurity, such as B (boron) or the like, is implanted into the second active region 10b using the second gate electrode 14b, the second offset spacer 16b, and the second sidewall 19B as a mask, thereby forming, in a self-aligned manner, a p-type source/drain region 23b having a relatively deep junction depth in a region of the silicon mixed-crystal layer 22 outside the second sidewall 19B in the second active region 10b.

Note that, in the step of FIG. 7A, a heat treatment for activating the impurities contained in the deep source/drain regions 23a and 23b is not performed immediately after formation of the deep n-type source/drain region 23a and the deep p-type source/drain region 23b, as is different from the second embodiment (see FIG. 3B).

Next, as shown in FIG. 7B, an underlying protection film 30 made of, for example, a silicon oxide film having a film thickness of 10 nm and a stressor insulating film 31 made of, for example, a silicon nitride film having a film thickness of 40 nm that has tensile stress are successively deposited on an entire surface of the semiconductor substrate 10 by, for example, CVD.

Next, as shown in FIG. 7C, a resist 32 covering the n-type MIS formation region NTR and having an opening in p-type MIS formation region PTR is formed on the semiconductor substrate 10, and thereafter, the stressor insulating film (silicon nitride film) 31 formed in the p-type MIS formation region PTR is removed by dry etching or wet etching under conditions such that a selection ratio with respect to the underlying protection film (silicon oxide film) 30 is set to be large, thereby exposing a surface of the underlying protection film 30 in the p-type MIS formation region PTR. Next, the resist 32 is removed, and thereafter, the semiconductor substrate 10 is subjected to, for example, a spike RTA treatment at 1050° C. In this case, tensile stress is applied in the gate length direction of the first gate electrode 14a and the channel region in the first active region 10a by SMT using the stressor insulating film 31, so that the states of the polysilicon crystal of the first gate electrode 14a and the silicon crystal of the first active region 10a are changed. Thereby, the first gate electrode 14a has an average grain size of polysilicon film (crystal grain size) larger than that of the second gate electrode 14b, and tensile stress is memorized in the gate length direction of the channel region in the first active region 10a.

Also in this case, the impurities contained in the deep n-type source/drain region 23a and the deep p-type source/drain region 23b can be activated.

Next, as shown in FIG. 8A, the stressor insulating film (silicon nitride film) 31 formed in n-type MIS formation region NTR is removed by dry etching or wet etching under etching conditions such that a selection ratio with respect to the underlying protection film (silicon oxide film) 30 is set to be large, thereby exposing a surface of the underlying protection film 30 in the n-type MIS formation region NTR. In this case, even after removal of the stressor insulating film 31, tensile stress is maintained in the memorized state in the gate length direction of the channel region in the first active region 10a. Next, the underlying protection film 30 is removed by dry etching or wet etching having a selection ratio with respect to the gate electrode formation film (polysilicon film) and the second insulating film (silicon nitride film), thereby exposing upper surfaces of the first and second gate electrodes 14a and 14b, and also exposing surfaces of the deep n-type source/drain region 23a and the deep p-type source/drain region 23b.

Next, as shown in FIG. 8B, by a step similar to the silicide layer forming step of FIG. 3B, first and second silicide layers 24a and 24b made of a nickel silicide film are formed in upper portions of the first and second gate electrodes 14a and 14b, and third and fourth silicide layers 25a and 25b made of a nickel silicide film are formed in upper portions of the deep n-type source/drain region 23a and the deep p-type source/drain region 23b.

In this case, the first gate electrode 14a is subjected to a heat treatment while only an upper surface thereof is in contact with the silicidation metal film. On the other hand, the second gate electrode 14b is subjected to the heat treatment while a side surface as well as an upper surface thereof are in contact with the silicidation metal film. Therefore, the formed second silicide layer 24b has a larger film thickness than that of the first silicide layer 24a.

Next, by performing a step similar to that of FIG. 3C in the first embodiment, an underlying insulating film, an interlayer insulating film, a contact plug and the like are formed on the semiconductor substrate 10, thereby obtaining a structure as shown in FIG. 3C.

According to this embodiment, an effect similar to that of the second embodiment is obtained. Specifically, the drive ability of the n-type MIS transistor can be improved in addition to an effect similar to that of the first embodiment.

In addition, after formation of the deep n-type source/drain region 23a and the deep p-type source/drain region 23b (see FIG. 7A), the step of memorizing tensile stress in the gate length direction of the channel region in the first active region 10a (see FIGS. 7B and 7C and FIG. 8A) is performed, thereby activating the impurities contained in the deep source/drain regions 23a and 23b using a heat treatment for memorizing tensile stress in the gate length direction of the channel region in the first active region 10a (see FIG. 7C). Therefore, it is not necessary to perform a heat treatment for activating the impurities contained in the deep source/drain regions 23a and 23b immediately after formation of the deep source/drain regions 23a and 23b (see FIG. 7A).

In other words, as is different from the second embodiment, it is not necessary to perform the heat treatment for memorizing tensile stress in the gate length direction of the channel region in the first active region 10a (see FIG. 6B) and the heat treatment for activating the impurities contained in the deep n-type source/drain region 23a and the deep p-type source/drain region 23b (see FIG. 3B) as additional separate steps. Therefore, the number of times of heat treatment can be reduced as compared to the second embodiment, thereby making it possible to reduce the number of steps.

Moreover, since the number of times of heat treatment is reduced, the number of times of diffusion of the impurities contained in the shallow source/drain regions 17a and 17b by a heat treatment performed after formation of the shallow n-type source/drain region 17a and the shallow p-type source/drain region 17b (see FIG. 1C) can be reduced, so that a deterioration in short channel characteristics can be reduced as compared to the second embodiment.

### Fourth Embodiment

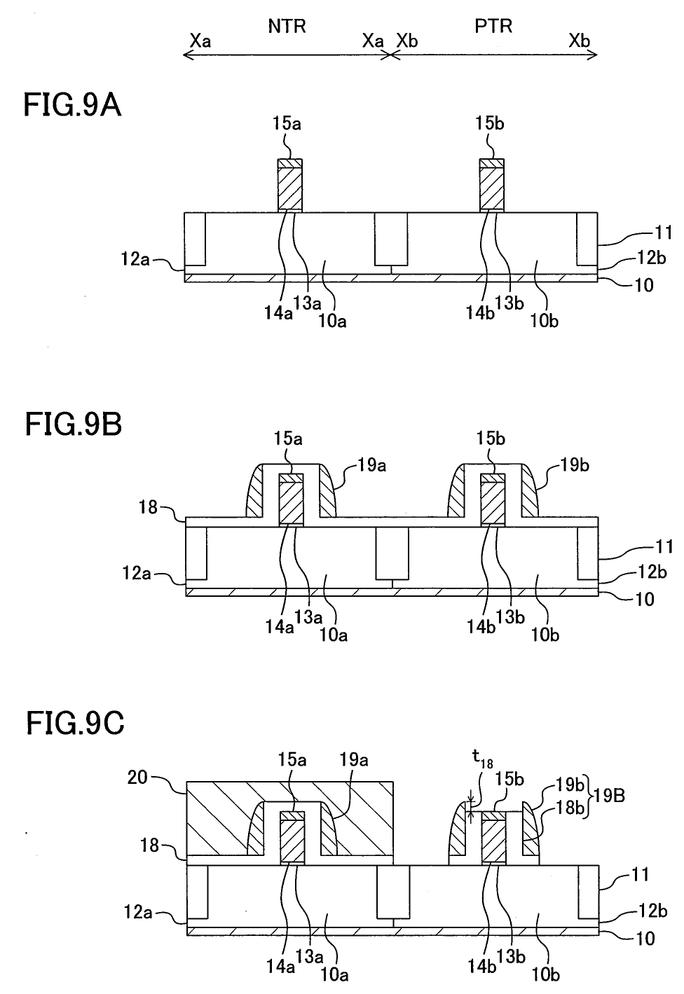

Hereinafter, a method for fabricating a semiconductor device according to a fourth embodiment of the present invention will be described with reference to FIGS. 9A to 9C, FIGS. 10A to 10C, and FIGS. 11A to 11C. FIGS. 9A to 9C, FIGS. 10A to 10C, and FIGS. 11A to 11C are cross-sectional views showing, in a gate length direction, major steps of the method for fabricating the semiconductor device of the fourth embodiment of the present invention in order of when the steps are performed. In these figures, an Xa-Xa region shown on the left-hand side indicates an n-type MIS formation region NTR, and an Xb-Xb region shown on the right-hand side indicates a p-type MIS formation region PTR. Here, in FIGS. 9A to 9C, FIGS. 10A to 10C, and FIGS. 11A to 11C, the same parts as those of the semiconductor device of the first embodiment are indicated by the same reference symbols and will not be described in detail.

Here, this embodiment is different from the first embodiment in terms of the fabricating method in the following points.

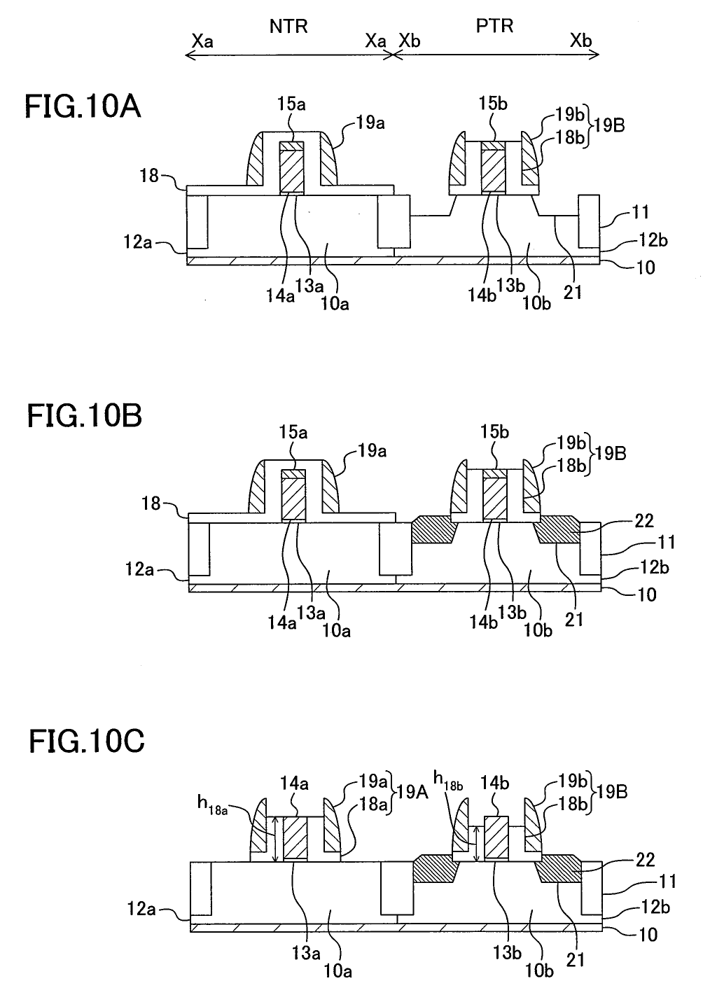

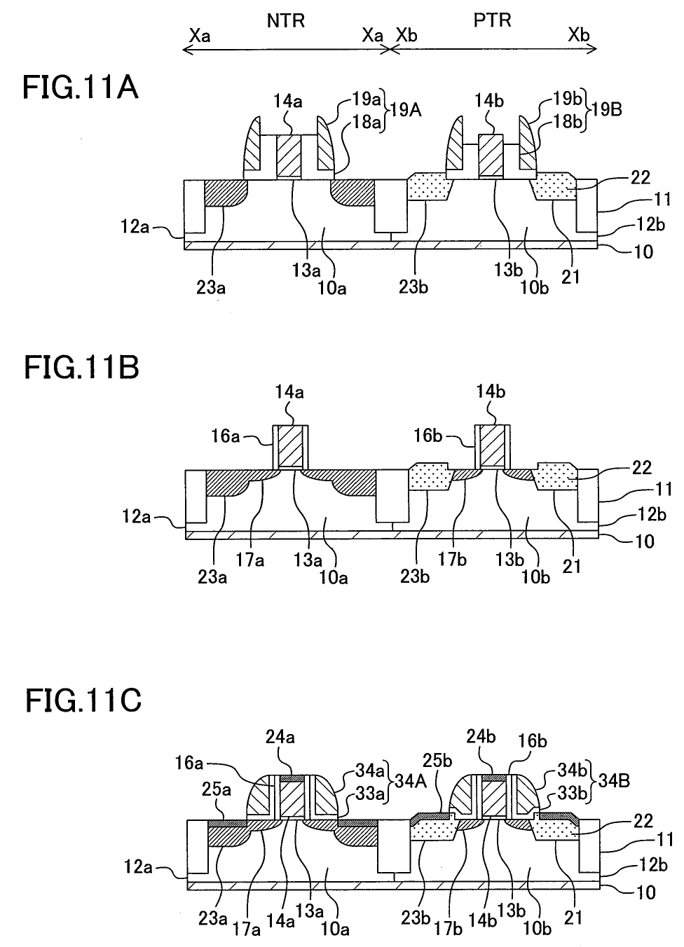

In the first embodiment, after formation of the shallow source/drain regions 17a and 17b (see FIG. 1C), formation of the silicon mixed-crystal layer 22 (see FIG. 2C) and formation of the deep source/drain regions 23a and 23b (see FIG. 3B) are performed. By contrast, in this embodiment, formation of the shallow source/drain regions 17a and 17b (se FIG. 11B) is performed after formation of the silicon mixed-crystal layer 22 (see FIG. 10B) and formation of the deep source/drain regions 23a and 23b (see FIG. 11A).

Initially, the steps of FIGS. 1A and 1B of the first embodiment are successively performed, thereby obtaining the structure of FIG. 1B.

Next, as shown in FIG. 9A, a protection film, a gate electrode formation film and a gate insulating film formation film are successively subjected to patterning by photolithography and dry etching, thereby forming a first gate insulating film 13a, a first gate electrode 14a and a first protection film 15a on a first active region 10a, and a second gate insulating film 13b, a second gate electrode 14b and a second protection film 15b on a second active region 10b.

Next, as shown in FIG. 9B, for example, a first insulating film 18 made of a silicon oxide film having a film thickness of 20 nm and a second insulating film made of a silicon nitride film having a film thickness of 30 nm are successively deposited on an entire surface of the semiconductor substrate 10 by, for example, CVD. Thereafter, the second insulating film (silicon nitride film) is etched by anisotropic dry etching under etching conditions such that a selection ratio with respect to the first insulating film (silicon oxide film) is set to be large. Thereby, a first outer sidewall 19a made of the second insulating film is formed on a side surface of the first gate electrode 14a with the first insulating film 18 being interposed between the first outer sidewall 19a and the first gate electrode 14a, while a second outer sidewall 19b made of the second insulating film is formed on a side surface of the second gate electrode 14b with the first insulating film 18 being interposed between the second outer sidewall 19b and the second gate electrode 14b. Thus, the first insulating film 18 is caused to remain, covering the first gate electrode 14a, the first active region 10a, the second gate electrode 14b, and the second active region 10b, without etching the first insulating film 18.

Next, as shown in FIG. 9C, a resist 20 covering the n-type MIS formation region NTR and having an opening in the p-type MIS formation region PTR is formed on the semiconductor substrate 10, and thereafter, the first insulating film (silicon oxide film) 18 formed in the p-type MIS formation region PTR is etched by anisotropic dry etching under conditions such that a selection ratio with respect to the second insulating film (silicon nitride film) is set to be large. Thereby, a surface of a region (source/drain formation region) outside the second outer sidewall 19b in the second active region 10b is exposed, and a second inner sidewall 18b made of the first insulating film 18 is formed. Thus, a second sidewall 19B including the second inner sidewall 18b having an L-shaped cross-section and the second outer sidewall 19b is formed on the side surface of the second gate electrode 14b.

In this case, a portion formed on an outer side of the second outer sidewall 19b and a portion formed on an inner side of the second outer sidewall 19b, of the first insulating film 18 of the p-type MIS formation region PTR, are removed. Therefore, as shown in FIG. 9C, an upper end height of the second inner sidewall 18b is lower by at least a film thickness of the first insulating film 18 (see FIG. 9C: t₁₈) than an upper surface height of the first insulating film 18 formed on the first gate electrode 14a in the n-type MIS formation region NTR.

Next, as shown in FIG. 10A, the resist 20 is removed, and thereafter, the second active region 10b whose surface is exposed is etched to a desired depth by dry etching having a selection ratio with respect to the first insulating film (silicon oxide film) and the second insulating film (silicon nitride film) or a succession of dry etching and wet etching having a selection ratio with respect to these films. Thereby, a trench 21 having a depth of, for example, 60 nm is formed in a region (i.e., the source/drain formation region) outside the second sidewall 19B in the second active region 10b of the p-type MIS formation region PTR. In this case, a surface of the first active region 10a in the n-type MIS formation region NTR is covered with the first insulating film 18, so that the first active region 10a is not etched. Also, the upper surface of the first gate electrode 14a is covered with the first protection film 15a and the first insulating film 18 successively, and the upper surface of the second gate electrode 14b is covered with the second protection film 15b, so that the first and second gate electrodes 14a and 14b are not etched.

Next, as shown in FIG. 10B, an etching residue, a spontaneous oxide film or the like in the trench 21 is removed by a hydrogen fluoride treatment, and thereafter, a silicon mixed-crystal layer 22 made of a p-type SiGe layer is epitaxially grown by, for example, CVD, specifically by supplying, for example, silane gas (SiH₄) and germane gas (GeH₄) along with p-type dopant gas, such as diborane gas (B₂H₆) or the like, at, for example, 650 to 700° C., so that the trench 21 is filled with the silicon mixed-crystal layer 22. In this case, since the surface of the first active region 10a in the n-type MIS formation region NTR is covered with the first insulating film 18, a SiGe layer is not epitaxially grown on the first active region 10a. Also, since the upper surface of the first gate electrode 14a is covered with the first protection film 15a and the first insulating film 18 and the upper surface of the second gate electrode 14b is covered with the second protection film 15b, a SiGe layer is not epitaxially grown on the first and second gate electrodes 14a and 14b.

Next, as shown in FIG. 10C, in the n-type MIS formation region NTR, the first insulating film (silicon oxide film) 18 and the first protection film (silicon oxide film) 15a are etched by dry etching having a selection ratio with respect to the gate electrode formation film (polysilicon film) and the second insulating film (silicon nitride film) or a succession of dry etching and wet etching having a selection ratio with respect to these films, so that a surface of a region (source/drain formation region) outside the first outer sidewall 19a in the first active region 10a and the upper surface of the first gate electrode 14a are exposed, and a first inner sidewall 18a made of the first insulating film 18 is formed. Thus, a first sidewall 19A including the first inner sidewall 18a having an L-shaped cross-section and the first outer sidewall 19a is formed on the side surface of the first gate electrode 14a. On the other hand, in the p-type MIS formation region PTR, the second protection film (silicon oxide film) 15b is etched so that the upper surface of the second gate electrode 14b is exposed. Thus, etching in the step of FIG. 10C is performed until the upper surface of the first gate electrode 14a, the surface of the first active region 10a (specifically, the surface of the source/drain formation region), and the upper surface of the second gate electrode 14b are exposed.

In this case, not only the first insulating film (silicon oxide film) 18 in the n-type MIS formation region NTR and the first and second protection films (silicon oxide films) 15a and 15b, but also the first and second offset spacers (silicon oxide films) 16a and 16b and the second inner sidewall (silicon oxide film) 18b that are made of the same material as that for those films (18, 15a and 15b) are also etched.

Here, in the previous step, i.e., the step of FIG. 10B, the upper end height of the second inner sidewall 18b in the p-type MIS formation region PTR is lower by at least the film thickness of the first insulating film 18 (see FIG. 9C: t₁₈) than the upper surface height of the first insulating film 18 formed on the first gate electrode 14a in the n-type MIS formation region NTR. Also, both the upper surface of the first insulating film 18 and the upper end of the second inner sidewall 18b are exposed. Therefore, in the step of FIG. 10C, both the exposed first insulating film 18 and second inner sidewall 18b are etched for the same etching time. Therefore, as shown in FIG. 10C, a height h_{18b} of an upper end of the second inner sidewall 18b is maintained lower by at least a film thickness of the first inner sidewall 18a than a height h₁₈ₐ of an upper end of the first inner sidewall 18a made of the first insulating film 18.

Thus, as shown in FIG. 10C, the upper end height h_{18b} of the second inner sidewall 18b is lower by at least the film thickness of the first inner sidewall 18a than the upper end height h₁₈ₐ of the first inner sidewall 18a. Therefore, the upper surface of the second gate electrode 14b protrudes above the upper end of the second inner sidewall 18b.

Next, as shown in FIG. 11A, an n-type impurity, such as As (arsenic) or the like, is implanted into the first active region 10a using the first gate electrode 14a and the first sidewall 19A as a mask by lithography and ion implantation so that an n-type source/drain region 23a having a relatively deep junction depth is formed, in a self-aligned manner, in a region outside the first sidewall 19A in the first active region 10a. On the other hand, a p-type impurity, such as B (boron) or the like, is implanted into the second active region 10b using the second gate electrode 14b and the second sidewall 19B as a mask so that a p-type source/drain region 23b having a relatively deep junction depth is formed, in a self-aligned manner, in a region of the silicon mixed-crystal layer 22 outside the second sidewall 19B in the second active region 10b.

Next, as shown in FIG. 11B, the first outer sidewall 19a and the second outer sidewall 19b made of the second insulating film (silicon nitride film) are removed by dry etching or wet etching having a selection ratio with respect to the first insulating film (silicon oxide film). Next, the first inner sidewall 18a and the second inner sidewall 18b made of the first insulating film (silicon oxide film) is removed by dry etching having a selection ratio with respect to the gate electrode formation film (polysilicon) and the semiconductor substrate (silicon). Thereafter, an offset spacer insulating film made of, for example, a silicon oxide film having a film thickness of 10 nm is deposited on an entire surface of the semiconductor substrate 10 by, for example, CVD, and thereafter, anisotropic etching is performed with respect to the offset spacer insulating film. Thereby, a first offset spacer 16a is formed on a side surface of the first gate electrode 14a, and a second offset spacer 16b is formed on a side surface of the second gate electrode 14b.

Thereafter, an n-type impurity, such as As (arsenic) or the like, is implanted into the first active region 10a by lithography and ion implantation using the first gate electrode 14a as a mask so that an n-type source/drain region (an LDD region or an extension region) 17a having a relatively shallow junction depth is formed, in a self-aligned manner, in a region outside the first gate electrode 14a in the first active region 10a. On the other hand, a p-type impurity, such as BF₂ or the like, is implanted into the second active region 10b using the second gate electrode 14b as a mask so that a p-type source/drain region (an LDD region or an extension region) 17b having a relatively shallow junction depth is formed, in a self-aligned manner, in a region outside the second gate electrode 14b in the second active region 10b. Thereafter, the impurities contained in the shallow n-type source/drain region 17a and the shallow p-type source/drain region 17b, and the deep n-type source/drain region 23a and the deep p-type source/drain region 23b are activated by a heat treatment.

Next, as shown in FIG. 11C, a third insulating film made of, for example, a silicon oxide film having a film thickness of 10 nm and a fourth insulating film made of, for example, a silicon nitride film having a film thickness of 30 nm are successively deposited on an entire surface of the semiconductor substrate 10 by, for example, CVD, and thereafter, the third and fourth insulating films are etched by anisotropic etching. Thereby, a third sidewall 34A including a third inner sidewall 33a made of the third insulating film having an L-shaped cross-section and a third outer sidewall 34a made of the fourth insulating film is formed on a side surface of the first gate electrode 14a with the first offset spacer 16a being interposed between the third sidewall 34A and the first gate electrode 14a. On the other hand, a fourth sidewall 34B including a fourth inner sidewall 33b made of the third insulating film having an L-shaped cross-section and a fourth outer sidewall 34b made of the fourth insulating film is formed on a side surface of the second gate electrode 14b with the second offset spacer 16b being interposed between the fourth sidewall 34B and second gate electrode 14b. Thereafter, by a step similar to the silicide layer forming step of FIG. 3B, first and second silicide layers 24a and 24b made of a nickel silicide film are formed in upper portions of the first and second gate electrodes 14a and 14b, and third and fourth silicide layers 25a and 25b made of a nickel silicide film are formed in upper portions of the deep n-type source/drain region 23a and the deep p-type source/drain region 23b.

Next, a step similar to the step of FIG. 3C of the first embodiment is performed, thereby forming an underlying insulating film, an interlayer insulating film, a contact plug and the like on the semiconductor substrate 10.

Thus, the semiconductor device of this embodiment can be fabricated.

According to this embodiment, an effect similar to that of the first embodiment can be obtained.

In addition, by forming the shallow source/drain regions 17a and 17b (see FIG. 11B) after formation of the silicon mixed-crystal layer 22 (see FIG. 10B) and formation of the deep source/drain regions 23a and 23b (see FIG. 11A), the shallow source/drain regions 17a and 17b are subjected to a heat treatment along with the deep source/drain regions 23a and 23b, i.e., a heat treatment is not performed with respect to the shallow source/drain regions 17a and 17b during formation of the silicon mixed-crystal layer 22. Therefore, the number of times of heat treatment performed after formation of the shallow source/drain regions 17a and 17b can be reduced, so that a deterioration in short channel characteristics can be prevented.

Although it has been described by way of a specific example in this embodiment that, in the step of FIG. 11B, after removal of the first outer sidewall 19a and the second outer sidewall 19b, the first inner sidewall 18a and the second inner sidewall 18b are perfectly removed, the present invention is not limited to this. Alternatively, after the first outer sidewall 19a and the second outer sidewall 19b are removed, bottom portions of the first inner sidewall 18a and the second inner sidewall 18b may be etched by anisotropic dry etching so that an offset spacer made of the first insulating film (first inner sidewall 18a) is formed on a side surface of the first gate electrode 14a instead of the first offset spacer 16a, and an offset spacer made of the first insulating film (the second inner sidewall 18b) may be formed on a side surface of the second gate electrode 14b instead of the second offset spacer 16b.

Although it has also been described by way of a specific example in this embodiment that, in the step of FIG. 11C, the third and fourth sidewalls 34A and 34B are multilayer sidewalls including the inner sidewalls 33a and 33b and the outer sidewalls 34a and 34b, the present invention is not limited to this. Alternatively, a single-layer sidewall made of a silicon oxide film or a silicon nitride film may be formed.

It has also been described by way of a specific example in the first and fourth embodiments and the variation of the first embodiment that, in a semiconductor device having a CMIS structure including an n-type MIS transistor and a p-type MIS transistor on the same substrate, the silicon mixed-crystal layer 22 made of a p-type SiGe layer is formed in the trench 21 formed in the active region of the p-type MIS transistor with accuracy, thereby effectively applying compressive stress in the gate length direction of the channel region in the active region of the p-type MIS transistor. The present invention is not limited to this.

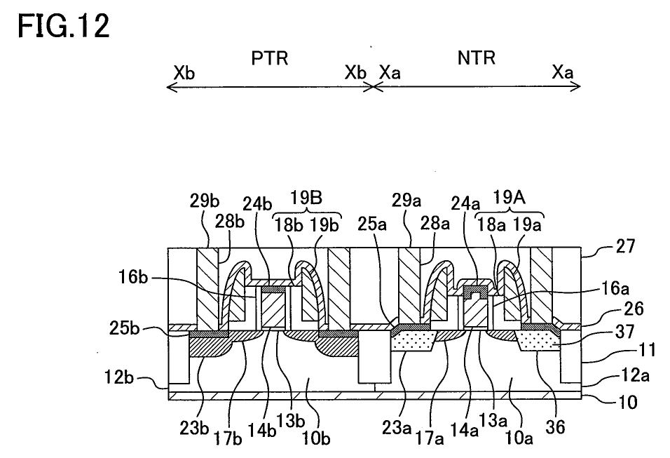

For example, the n-type MIS formation region NTR and the p-type MIS formation region PTR in the first embodiment may be switched. As shown in FIG. 12, a silicon mixed-crystal layer 37 made of an n-type SiC layer instead of a p-type SiGe layer may be formed in a trench 36 formed in an active region 10a of the n-type MIS transistor with accuracy. Thereby, tensile stress can be effectively applied in the gate length direction of the channel region in the active region of the n-type MIS transistor. Note that the silicon mixed-crystal layer 37 made of an n-type SiC layer may be formed by epitaxially growing an n-type SiC layer by, for example, CVD so that the trench 36 formed in a region (source/drain formation region) outside the sidewall 19A in the active region 10a of the n-type MIS transistor is filled with the n-type SiC layer.

In the case of the semiconductor device having the silicon mixed-crystal layer 37 made of an SiC layer in the source/drain formation region of the n-type MIS transistor, the upper end height of the inner sidewall 18a of the n-type MIS formation region NTR is lower by at least the film thickness of the inner sidewall 18b than the upper end height of the inner sidewall 18b of the p-type MIS formation region PTR as shown in FIG. 12. Also, the upper end height of the offset spacer 16a of the n-type MIS formation region NTR is lower by at least the film thickness of the inner sidewall 18b than the upper end height of the offset spacer 16b of the p-type MIS formation region PTR. The silicide layer 24a of the n-type MIS formation region NTR has a larger film thickness than that of the silicide layer 24b of the p-type MIS formation region PTR.

As described above, the present invention is useful for a semiconductor device having a CMIS structure in which a silicon mixed-crystal layer is provided either in the source/drain formation region of the n-type MIS transistor or in the source/drain formation region of the p-type MIS transistor, and a method for fabricating the semiconductor device.

What is claimed is:

1. A semiconductor device comprising a first MIS transistor and a second MIS transistor, wherein
the first MIS transistor includes:
a first active region surrounded by an isolation region in a semiconductor substrate;
a first gate insulating film formed on the first active region;
a first gate electrode formed on the first gate insulating film; and
a first sidewall formed on a side surface of the first gate electrode, and including a first inner sidewall having an L-shaped cross-section and a first outer sidewall formed on the first inner sidewall, and
the second MIS transistor includes:
a second active region surrounded by the isolation region in the semiconductor substrate;
a second gate insulating film formed on the second active region;
a second gate electrode formed on the second gate insulating film;
a second sidewall formed on a side surface of the second gate electrode, and including a second inner sidewall having an L-shaped cross-section and a second outer sidewall formed on the second inner sidewall;
a trench provided in a region outside the second sidewall in the second active region; and
a silicon mixed-crystal layer formed in the trench, for causing first stress in a gate length direction of a channel region in the second active region,
wherein a height of an upper end of the second inner sidewall is lower than a height of an upper end of the first inner sidewall.

2. The semiconductor device of claim 1, wherein
the upper end height of the second inner sidewall is lower by at least a film thickness of the first inner sidewall than the upper end height of the first inner sidewall.

3. The semiconductor device of claim 1, further comprising:
a first silicide layer formed on the first gate electrode; and
a second silicide layer formed on the second gate electrode,
wherein the second silicide layer has a larger film thickness than that of the first silicide layer.

4. The semiconductor device of claim 1, wherein
the first inner sidewall and the second inner sidewall are made of a silicon oxide film, and
the first outer sidewall and the second outer sidewall are made of a silicon nitride film.

5. The semiconductor device of claim 1, further comprising:
a first offset spacer formed between the side surface of the first gate electrode and the first sidewall; and
a second offset spacer formed between the side surface of the second gate electrode and the second sidewall.

6. The semiconductor device of claim 1, further comprising:
a first-conductivity type source/drain region formed in a region outside the first sidewall in the first active region; and
a second-conductivity type source/drain region formed in a region including the silicon mixed-crystal layer outside the second sidewall in the second active region.

7. The semiconductor device of claim 1, wherein
second stress is applied, in a gate length direction, to a channel region in the first active region;
the first stress is applied, in the gate length direction, to a channel region in the second active region;
the second stress is tensile stress; and
the first stress is compressive stress.

8. The semiconductor device of claim 1, wherein
the first gate electrode and the second gate electrode have different average grain sizes of silicon film.

9. The semiconductor device of claim 1, wherein
the first MIS transistor is an n-type MIS transistor,
the second MIS transistor is a p-type MIS transistor,
the silicon mixed-crystal layer is made of a SiGe layer, and
the first stress is compressive stress.

10. The semiconductor device of claim 1, wherein
the first MIS transistor is a p-type MIS transistor,
the second MIS transistor is an n-type MIS transistor,
the silicon mixed-crystal layer is made of a SiC layer, and
the first stress is tensile stress.

11. A method for fabricating a semiconductor device, wherein
the semiconductor device comprises a first MIS transistor having a first gate insulating film and a first gate electrode and a second MIS transistor having a second gate insulating film and a second gate electrode,
the method comprises the steps of:
(a) forming a first active region and a second active region surrounded by an isolation region in a semiconductor substrate;
(b) forming the first gate insulating film and the first gate electrode on the first active region, and forming the second gate insulating film and the second gate electrode on the second active region;
(c) after step (b), successively forming a first insulating film and a second insulating film on the semiconductor substrate;
(d) etching the second insulating film to form a first outer sidewall on a side surface of the first gate electrode with the first insulating film being interposed between the first outer sidewall and the first gate electrode, and to form a second outer sidewall on a side surface of the second gate electrode with the first insulating film being interposed between the second outer sidewall and the second gate electrode;
(e) after step (d), etching the first insulating film on the second active region to form a second inner sidewall having an L-shaped cross-section between the second gate electrode and the second outer sidewall, thereby forming a second sidewall including the second inner sidewall and the second outer sidewall;
(f) forming a trench in a region outside the second sidewall in the second active region;
(g) selectively forming, in the trench, a silicon mixed-crystal layer for causing first stress in a gate length direction of a channel region in the second active region; and
(h) after step (g), etching the first insulating film on the first active region to form a first inner sidewall having an L-shaped cross-section between the first gate electrode and the first outer sidewall, thereby forming a first sidewall including the first inner sidewall and the first outer sidewall.

12. The method of claim 11, wherein
step (h) includes etching the second inner sidewall, and
a height of an upper end of the second inner sidewall is lower than a height of an upper end of the first inner sidewall.

13. The method of claim 11, wherein
the first inner sidewall and the second inner sidewall are made of a silicon oxide film, and
the first outer sidewall and the second outer sidewall are made of a silicon nitride film.

14. The method of claim 11, further comprising:
(i) after step (h), forming a first first-conductivity type source/drain region in a region outside the first sidewall in the first active region, and forming a first second-conductivity type source/drain region in a region including the silicon mixed-crystal layer outside the second sidewall in the second active region.

15. The method of claim 11, further comprising:
(j) after step (h), forming a first silicide layer on the first gate electrode, and forming a second silicide layer on the second gate electrode,
wherein the second silicide layer has a larger film thickness than that of the first silicide layer.

16. The method of claim 11, further comprising:
(k) after step (d) and before step (e), forming a surface protection film on the semiconductor substrate,
wherein step (e) includes etching the surface protection film on the second active region before etching the first insulating film on the second active region, and
step (h) includes etching the surface protection film on the first active region before etching the first insulating film on the first active region.

17. The method of claim 11, further comprising:
(l) after step (g) and before step (h), or after step (h), memorizing second stress in a channel region of the first active region,
wherein the second stress is tensile stress, and
the first stress is compressive stress.

18. The method of claim 17, wherein
step (l) includes (l1) forming a stressor insulating film on the semiconductor substrate, (l2) removing the stressor insulating film on the second active region, (l3) after step (l2), performing a heat treatment with respect to the semiconductor substrate, and (l4) after step (l3), removing the stressor insulating film on the first active region, and
in step (l3), the second stress is applied from the stressor insulating film on the first active region to the first active region by the heat treatment, so that the second stress is memorized in the channel region of the first active region.

19. The method of claim 11, wherein
the first MIS transistor is an n-type MIS transistor,
the second MIS transistor is a p-type MIS transistor,
step (g) is a step of forming a SiGe layer as the silicon mixed-crystal layer, and
the first stress is compressive stress.

20. The method of claim 11, wherein
the first MIS transistor is a p-type MIS transistor,
the second MIS transistor is an n-type MIS transistor,
step (g) is a step of forming a SiC layer as the silicon mixed-crystal layer, and
the first stress is tensile stress.

21. The method of claim 14, further comprising:
(m) after step (i), removing the first sidewall and the second sidewall; and
(n) after (m), forming a second first-conductivity type source/drain region in a region outside the first gate electrode in the first active region, and forming a second second-conductivity type source/drain region in a region outside the second gate electrode in the second active region,
wherein the second first-conductivity type source/drain region has a junction depth shallower than that of the first first-conductivity type source/drain region, and
the second second-conductivity type source/drain region has a junction depth shallower than that of the first second-conductivity type source/drain region.
